(19) United States
(12) Patent Application Publication
(10) Pub. No.: US 2021/0018666 A1
(43) Pub. Date: Jan. 21, 2021

(54) POLARIZING FILM, METHOD FOR MANUFACTURING SAME, OPTICAL FILM, AND IMAGE DISPLAY DEVICE

(71) Applicant: NITTO DENKO CORPORATION, Ibaraki-shi, Osaka (JP)

(72) Inventors: Ryo KANNO, Ibaraki-shi (JP); Masayuki OKAMOTO, Ibaraki-shi (JP); Noritsugu DAIGAKU, Ibaraki-shi (JP); Tatsuya YAMASAKI, Ibaraki-shi (JP)

(73) Assignee: Nitto Denko Corporation, Ibaraki-shi, Osaka (JP)

(21) Appl. No.: 16/975,451

(22) PCT Filed: Feb. 19, 2019
(86) PCT No.: PCT/JP2019/006038

§ 371 Date: Aug. 25, 2020

(30) Foreign Application Priority Data
Feb. 26, 2018 (JP) 2018-032243
Feb. 5, 2019 (JP) 2019-018517

(51) Int. Cl. G02B 5/30; G02F 1/1335; G02B 1/18; G02B 1/12; G02B 1/14

(52) U.S. Cl. CPC G02B 5/305; G02F 1/133528; G02B 1/14; G02B 1/12; G02B 1/18

(57) ABSTRACT

A polarizing film has a transparent protective film provided on at least one side of a polarizer through an adhesive layer. The transparent protective film is a cellulose-based resin film. The adhesive layer is formed by a cured layer obtained by irradiating an active energy ray-curable adhesive composition with active energy rays. The composition contains 0.0% by weight to 4.0% by weight of an active energy ray-curable compound (A) having an SP value of 29.0 (MJ/m³)^{1/2} to 32.0 (MJ/m³)^{1/2}, 5.0% by weight to 98.0% by weight of an active energy ray-curable compound (B) having the SP value of 18.0 (MJ/m³)^{1/2} to 21.0 (MJ/m³)^{1/2} (exclusive of 21.0 (MJ/m³)^{1/2}), and 5.0% by weight to 98.0% by weight of an active energy ray-curable compound (C) having the SP value of 21.0 (MJ/m³)^{1/2} to 26.0 (MJ/m³)^{1/2} on a basis of 100% by weight of a total amount of the composition.

### TECHNICAL FIELD

The present invention relates to a polarizing film in which a transparent protective film is provided on at least one side of a polarizer through an adhesive layer and a method for manufacturing the polarizing film. The polarizing film can form an image display device such as a liquid crystal display device (LCD), an organic EL display device, a CRT, and a PDP independently or as an optical film formed by laminating the polarizing films.

### BACKGROUND ART

A polarizing film is used in each type of the image display devices for image display. For example, it is essential in a liquid crystal display device (LCD) to arrange a polarizing film on each side of the glass substrate that forms the surface of the liquid crystal panel because of its image forming system. In an organic electro-luminescent display device, a circular polarizing film in which a polarizing film and a quarter wavelength plate are laminated is arranged on the view side of the organic light emitting layer in order to block specular reflection of the light from outside at the metal electrodes.

In general, a protective film is laminated onto one side or both sides of a polarizer formed of a polyvinyl alcohol film and a dichroic material such as iodine with a polyvinyl alcohol adhesive, an active energy ray-curable adhesive, etc. and used as the polarizing film.

Under a harsh environment where thermal shock is applied on the polarizing film (for example, a thermal shock test in which the temperature is changed between −40° C. and 85° C. reputably), there is a problem that a crack (a through crack) can easily occur over the whole in the absorption axis direction of the polarizer due to the change of shrinkage stress of the polarizer. In order to suppress the shrinkage of the polarizer and reduce the influence of thermal shock, the thickness of the polarizer is made smaller. If the polarizer is a thin polarizer with a thickness of 10 μm or less, the change of shrinkage stress becomes small, which suppresses the shrinking of the polarizer and reduce the influence of thermal shock, and the through crack is less likely to occur. For example, a polarizing film is disclosed in which a protective film is laminated onto one side or both sides of a thin polarizer with a thickness of 10 μm or less and the occurrence of the through crack is suppressed (refer to Patent Document 1).

On the other hand, there is a problem that the optical properties of a thin polarizer with a thickness of 10 μm or less easily deteriorate in a humidified environment. In Patent Document 2, a resin film with an extremely low moisture permeability is used as a protective film of the thin polarizer to suppress the deterioration of the polarizer due to humidification.

In recent years, a polarizing plate has been used also in a meter display of an automobile, a smart watch, etc. From the design properties, it has been desired to use a polarizing plate having a shape other than a rectangular shape, to form a through hole in the polarizing plate, etc. (refer to Patent Document 3). In this kind of process of making an irregular polarizing plate, the demand has been increased for unconventional processes such as small-hole processing and small-diameter concave R-processing which are more delicate, finer, and more complicated compared to the conventional processes. It was found that a crack tends to occur easily in the recessed part created by the small-hole processing or the small-diameter concave R-processing compared to a rectangular polarizing plate.

### PRIOR ART DOCUMENTS

### Patent Documents

Patent Document 1: JP-A-2015-152911

Patent Document 2: JP-A-2017-211433

Patent Document 3: JP-A-2018-12182

### SUMMARY OF THE INVENTION

### Problems to be Solved by the Invention

In the technique disclosed in Patent Document 2, a polarizing film in which a resin film with an extremely low moisture permeability is used as a protective film of the thin polarizer is used to suppress the deterioration of the thin polarizer in a humidified environment and the occurrence of a crack during thermal shock. However, durability of the polarizing film has been desired that can pass a severer crack test evaluating the presence of a crack during thermal shock in the part of the irregular polarizing film that has gone through small-hole processing or small-diameter concave R-processing of recent years. The fact is, however, that the durability against the crack can be improved further of the polarizing films that have been reported so far.

In view of the fact described above, the objective of the present invention is to provide a polarizing film that is capable of suppressing the deterioration of the optical properties in a humidified environment and achieving excellent crack resistance that is especially desired for an irregular polarizing film that has gone through small-hole processing or small-diameter concave R-processing, and to provide a method for manufacturing the polarizing film.

Furthermore, the objective of the present invention is to provide an image display device using an optical film in which at least one of the polarizing films are laminated, the polarizing film, and/or the optical film.

### Means for Solving the Problems

The above-described problem can be solved by the configuration described below. The present invention relates to a polarizing film in which a transparent protective film is provided on at least one side of a polarizer through an adhesive layer; the transparent protective film is a cellulose-based resin film; the adhesive layer is formed by a cured layer obtained by irradiating an active energy ray-curable adhesive composition with active energy rays; and the active energy ray-curable adhesive composition contains 0.0% by weight to 4.0% by weight of an active energy ray-curable compound (A) having the SP value of 29.0 (MJ/m³)^{1/2} to 32.0 (MJ/m³)^{1/2}, 5.0% by weight to 98.0% by weight of an active energy ray-curable compound (B) having the SP value of 18.0 (MJ/m³)^{1/2} to 21.0 (MJ/m³)^{1/2} (exclusive of 21.0 (MJ/m³)^{1/2}), and 5.0% by weight to 98.0% by weight of an active energy ray-curable compound (C) having the SP value of 21.0 (MJ/m³)^{1/2} to 26.0 (MJ/m³)^{1/2} on the basis of 100% by weight of the total amount of the composition.

According to the polarizing film, the thickness of the polarizer is preferably 3 μm to 15 μm.

According to the polarizing film, the active energy ray-curable adhesive composition preferably contains 20% by weight to 80% by weight of the active energy ray-curable compound (B) on the basis of 100% by weight of the total amount of the composition.

According to the polarizing film, the active energy ray-curable adhesive composition preferably contains an acrylic oligomer (D) obtained by polymerizing a (meth)acrylic monomer.

According to the polarizing film, the acrylic equivalent Cₐₑ of the active energy ray-curable adhesive composition represented by a following equation (1) is preferably 140 or more.

Cₐₑ=1/Σ(W_{N}/Nₐₑ) (1)

In the equation (1), W_{N} represents a mass fraction of an active energy ray-curable compound N in the composition, and Nₐₑ represents an acrylic equivalent of the active energy ray-curable compound N.

According to the polarizing film, the active energy ray-curable adhesive composition preferably contains a radical polymerization initiator having a hydrogen extraction effect.

According to the polarizing film, the radical polymerization initiator is preferably a thioxanthone-based radical polymerization initiator.

According to the polarizing film, the active energy ray-curable adhesive composition contains the acrylic oligomer (D); in which a compatible layer is formed between the transparent protective film and the adhesive layer, where a composition thereof changes continuously; and the value of P×Q is preferably less than 10, where P (μm) represents the thickness of the compatible layer and Q (% by weight) represents a content of the acrylic oligomer (D) on the basis of 100% by weight of the total amount of the composition.

The polarizing film has a compound represented by a following formula (1):

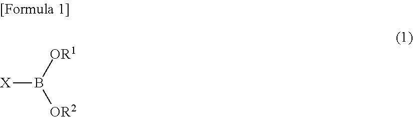

(wherein, X represents a functional group including a reactive group and R¹ and R² represent each independently a hydrogen atom, an aliphatic hydrocarbon group which may have a substituent, an aryl group which may have a substituent, or a heterocyclic group which may have a substituent) provided on at least one of the laminating sides of the polarizer and the transparent protective film, and the compound represented by the formula (1) preferably lies between the polarizer and the adhesive layer and/or between the transparent protective film and the adhesive layer.

According to the polarizing film, the compound represented by the formula (1) is preferably a compound represented by a following formula (1′):

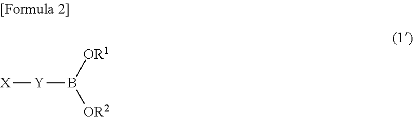

(wherein, Y represents an organic group; and X, R¹, and R² are the same as described above).

The polarizing film preferably has the compound represented by the formula (1) on the laminating side of the polarizer.

According to the polarizing film, the reactive group in the compound represented by the formula (1) is preferably at least one type of the reactive groups selected from a group consisting of α,β-unsaturated carbonyl group, a vinyl group, a vinylether group, an epoxy group, an oxetane group, an amino group, an aldehyde group, a mercapto group, and a halogen group.

The present invention relates to a method for manufacturing a polarizing film including a coating step of coating an active energy ray-curable adhesive composition on at least one of the sides of a polarizer and a transparent protective film, a step of laminating the polarizer and the transparent protective film, and an adhering step of adhering the transparent protective film to the polarizer through an adhesive layer obtained by irradiating the polarizer or the transparent protective film with active energy rays to cure the active energy ray-curable adhesive composition; in which the transparent protective film is a cellulose-based resin film, and the active energy ray-curable adhesive composition contains 0.0% by weight to 4.0% by weight of an active energy ray-curable compound (A) having the SP value of 29.0 (MJ/m³)^{1/2} to 32.0 (MJ/m³)^{1/2}, 5.0% by weight to 98.0% by weight of an active energy ray-curable compound (B) having the SP value of 18.0 (MJ/m³)^{1/2} to 21.0 (MJ/m³)^{1/2} (exclusive of 21.0 (MJ/m³)^{1/2})) and 5.0% by weight to 98.0% by weight of an active energy ray-curable compound (C) having the SP value of 21.0 (MJ/m³)^{1/2} to 26.0 (MJ/m³)^{1/2} on the basis of 100% by weight of the total amount of the composition.

The method for manufacturing a polarizing film preferably contains an adhesion facilitating treatment step of attaching the compound represented by the following formula (1):

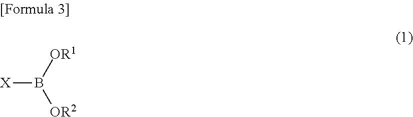

(wherein, X represents a functional group including a reactive group and R¹ and R² represent each independently a hydrogen atom, an aliphatic hydrocarbon group which may have a substituent, an aryl group which may have a substituent, or a heterocyclic group which may have a substituent) onto at least one of the laminating sides of the polarizer and the transparent protective film.

According to the method for manufacturing a polarizing film, the compound represented by the Formula (1) is preferably a compound represented by the following formula (1′):

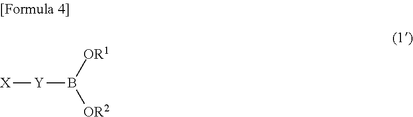

(wherein, Y represents an organic group, and X, R¹, and R² are the same as described above).

According to the method for manufacturing a polarizing film, a corona treatment, a plasma treatment, an excimer treatment, or a frame treatment is preferably performed on the laminating side which is at least one of the sides of the polarizer and the transparent protective film before the coating step.

According to the method for manufacturing a polarizing film, the active energy rays preferably contain visible rays having a wavelength region of 380 nm to 450 nm

According to the method for manufacturing a polarizing film, the ratio of the integral illuminance of a wavelength region of 380 nm to 440 nm of the active energy rays to the integral illuminance of a wavelength region of 250 nm to 370 nm of the active energy rays is preferably 100:0 to 100:50.

Furthermore, the present invention relates to an image display device using an optical film in which at least any one of the polarizing films are laminated, any one of the polarizing films, and/or the optical films.

### Effect of the Invention

As described above, it is difficult for not only an irregular polarizing film that has gone through small-hole processing or small-diameter concave R-processing but also a normal rectangular polarizing film to suppress the deterioration of the optical properties in a humidified environment and to have excellent crack resistance due to various causes. It was found by earnest investigation of the present inventors that the deterioration of the optical properties can be suppressed and an excellent crack resistance can be achieved by developing an active energy ray-curable adhesive composition (i) that is capable of forming an adhesive layer with an improved adhesive property between a polarizer and a transparent protective film and an improved optical durability, selecting an optimal transparent protective film (ii), and putting the optimal transparent protective film and (i) together.

The active energy ray-curable adhesive composition (i) will be explained. In order to form an adhesive layer with an improved adhesive property between a polarizer and a transparent protective film and an improved optical durability, the active energy ray-curable adhesive composition of the present invention contains at least an active energy ray-curable compound (A), an active energy ray-curable compound (B), and an active energy ray-curable compound (C). The SP value of the active energy ray-curable compound (A) is 29.0 (MJ/m³)^{1/2} to 32.0 (MJ/m³)^{1/2}, and the composition ratio of the active energy ray-curable compound (A) is 0.0% by weight to 4.0% by weight on the basis of 100% by weight of the total amount of the composition. The active energy ray-curable compound (A) has a high SP value and greatly contributes to improve the adhesive property of the adhesive layer with a polarizer such as PVA based polarizer (SP value of 32.8) and a transparent protective layer such as saponified triacetyl cellulose (SP value of 32.7). On the other hand, if the content of the active energy ray-curable compound (A) in the active energy ray-curable adhesive composition is high, the optical durability deteriorates. Therefore, the upper limit of the active energy ray-curable compound (A) is preferably 4.0% by weight, more preferably 2.0% by weight, preferably 1.5% by weight, further preferably 1.0% by weight, and the active energy ray-curable adhesive composition especially preferably does not contain the active energy ray-curable compound (A) on the basis of 100% by weight of the total amount of the composition.

The SP value of the active energy ray-curable compound (B) is 18.0 (MJ/m³)¹² to 21.0 (MJ/m³)^{1/2} (exclusive of 21.0 (MJ/m³)^{1/2}) and the composition ratio of the active energy ray-curable compound (B) is 5.0% by weight to 98.0% by weight. The active energy ray-curable compound (B) has a low SP value that is much lower than the SP value of water (47.9) and greatly contributes to improve the water resistance of the adhesive layer. The composition ratio of the active energy ray-curable compound (B) is preferably 20% by weight to 80% by weight and more preferably 25% by weight to 70% by weight on the basis of 100% by weight of the total amount of the composition.

The SP value of the active energy ray-curable compound (C) is 21.0 (MJ/m³)^{1/2} to 26.0 (MJ/m³)^{1/2}, and the composition ratio of the active energy ray-curable compound (C) is 5.0% by weight to 98.0% by weight. Because the SP value of the active energy ray-curable compound (C) is close to the SP value of a transparent protective film such as the SP value of un-saponified triacetyl cellulose (23.3) and the SP value of an acrylic film (22.2), the active energy ray-curable compound (C) contributes to improve the adhesive property of the adhesive layer with these transparent protective films. The composition ratio of the active energy ray-curable compound (C) is preferably 20% by weight to 80% by weight and more preferably 25% by weight to 70% by weight on the basis of 100% by weight of the total amount of the composition.

In the present invention a specific transparent protective film (ii) is adhered to a polarizer by the active energy ray-curable adhesive composition (i).

A cellulose-based resin film can be used as the transparent protective film (ii). The dimensional change of the cellulose-based resin film is small during thermal shock and the linear expansion coefficient is low. On the other hand, the moisture permeability is high. Therefore, there are both positive and negative aspects on using the cellulose-based resin film for suppressing the deterioration of the optical properties in a humidified environment and achieving excellent crack resistance of the polarizing film. However, the transparent protective film is adhered to the polarizer using an adhesive layer formed by a cured layer of the active energy ray-curable adhesive composition (i), which makes up the negative aspect of the cellulose-based resin film and makes it possible to solve both problems.

The polarizing film according to the present invention is preferable configured by adhering the specific transparent protective film (ii) to the specific polarizer (iii) having the thickness of 3 μm to 15 μm through an adhesive layer formed by a cured layer of the specific active energy ray-curable adhesive composition (i), since the deterioration of the optical properties of the polarizing film in a humidified environment can be suppressed and the excellent crack resistance of the polarizing film can be achieved.

### BRIEF DESCRIPTION OF THE DRAWINGS

FIG. 1 is a schematic drawing of a polarizing film with a pressure-sensitive adhesive layer on which a crack evaluation test was performed.

### MODE FOR CARRYING OUT THE INVENTION

The polarizing film according to the present invention is configured by adhering a specific transparent protective film to a specific polarizer through an adhesive layer formed by a cured layer of a specific active energy ray-curable adhesive composition.

### <Active Energy Ray-Curable Adhesive Composition>

The active energy ray-curable adhesive composition contains active energy ray-curable compounds (A), (B), and (C) as curable components. Specifically, the active energy ray-curable adhesive composition contains 0.0% by weight to 4.0% by weight of the active energy ray-curable compound (A) having the SP value of 29.0 (MJ/m³)^{1/2} to 32.0 (MJ/m³)^{1/2}, 5.0% by weight to 98.0% by weight of the active energy ray-curable compound (B) having the SP value of 18.0 (MJ/m³)^{1/2} to 21.0 (MJ/m³)^{1/2} (exclusive of 21.0 (MJ/m³)^{1/2}), and 5.0% by weight to 98.0% by weight of the active energy ray-curable compound (C) having the SP value of 21.0 (MJ/m³)^{1/2} to 26.0 (MJ/m³)^{1/2} on the basis of 100% by weight of the total amount of the composition. In the present invention, “the total amount of the composition” means the total amount of the composition including various types of initiators and additives in addition to the active energy ray-curable compounds.

The method for calculating the SP value (solubility parameter) in the present invention will be explained below.

### (Method for Calculating the Solubility Parameter (SP Value))

In the present invention, the SP values of the active energy ray-curable compound, the polarizer, various types of the transparent protective films can be obtained by a Fedors' method referred to Polymer Eng. & Sci. 1974; 14(2):148-154, that is,

$$δ = {[ \frac{{\sum }_{i} Δ {e}_{i}}{{\sum }_{i} Δ {v}_{i}} ]}^{1 \text{/} 3} \qquad [ Expression 1 ]$$

(wherein, Δeᵢ represents an evaporation energy at 25° C. of an atom or a group, and Δvᵢ represents a molar volume at 25° C. of an atom or a group).

In the above expression, each of Δeᵢ and Δvᵢ is constant given to the i^{th} atom or group in the main molecular. The values of Δe and Δv for some typical types of the atoms and the groups are shown in Table 1.

TABLE 1

| Atom or group | Δe (J/mol) | Δv (cm³/mol) |
|---|---|---|
| CH₃ | 4086 | 33.5 |
| C | 1465 | −19.2 |
| Phenyl | 31940 | 71.4 |
| Phenylene | 31940 | 52.4 |
| COOH | 27628 | 28.5 |
| CONH₂ | 41861 | 17.5 |
| NH₂ | 12558 | 19.2 |
| —N═ | 11721 | 5.0 |
| CN | 25535 | 24.0 |
| NO₂ (fatty acid) | 29302 | 24.0 |
| NO₃ (aromatic) | 15363 | 32.0 |
| O | 3349 | 3.8 |
| OH | 29805 | 10.0 |
| S | 14149 | 12.0 |
| F | 4186 | 18.0 |
| Cl | 11553 | 24.0 |
| Br | 15488 | 30.0 |

The active energy ray-curable compound (A) can be used without limitation as long as the active energy ray-curable compound (A) is a compound having a radical polymerization group and having the SP value of 29.0 (MJ/m³)^{1/2} to 32.0 (MJ/m³)^{1/2}. Specific examples of the active energy ray-curable compound (A) include hydroxylethylacrylamide (SP value 29.5) and N-methylolacrylamide (SP value 31.5). The (meth)acrylate group in the present invention means an acrylate group and/or a methacrylate group.

The active energy ray-curable compound (B) can be used without limitation as long as the active energy ray-curable compound (B) is a compound having a radical polymerization group and having the SP value of 18.0 (MJ/m³)^{1/2} to 21.0 (MJ/m³)^{1/2} (exclusive of 21.0 (MJ/m³)^{1/2}). Specific examples of the active energy ray-curable compound (B) include tripropylene glycol diacrylate (SP value 19.0), 1,9-nonane diol diacrylate (SP value 19.2), tricyclodecane dimethanol diacrylate (SP value 20.3), cyclotrimethylolpropane formal acrylate (SP value 19.1), dioxane glycol diacrylate (SP value 19.4), and EO-modified diglycerol tetraacrylate (SP value 20.9). The commercial products may be preferably used as the active ray-curable compound (B), and examples include ARONIX M-220 (manufactured by TOAGOSAI CO., LTD., SP value 19.0), LIGHT ACRYLATE 1,9ND-A (manufactured by KYOEI CHEMICAL, CO., LTD, SP value 19.2), LIGHT ACRYLATE DGE-4A (manufactured by KYOEI CHEMICAL, CO., LTD, SP value 20.9), LIGHT ACRYLATE DCP-A (manufactured by KYOEI CHEMICAL, CO., LTD, SP value 20.3), SR-531 (manufactured by SARTOMER, SP value 19.1), and CD-536 (manufactured by SARTOMER, SP value 19.4).

The active energy ray-curable compound (C) can be used without limitation as long as the active energy ray-curable compound (B) is a compound having a radical polymerization group and having the SP value of 21.0 (MJ/m³)^{1/2} to 26.0 (MJ/m³)^{1/2}. Specific examples of the active energy ray-curable compound (C) include acryloylmorpholine (SP value 22.9), N-methoxymethylacrylamide (SP value 22.9), and N-ethoxymethylacrylamide (SP value 22.3). The commercial products may be preferably used as the active energy ray-curable compound (C), and examples include ACMO (manufactured by KOHJIN Film & Chemicals Co., Ltd., SP value 22.9), Wasmer 2MA (manufactured by Kasano Kosan Co., Ltd., SP value 22.9), Wasmer EMA (manufactured by Kasano Kosan Co., Ltd., SP value 22.3), and Wasmer 3MA (manufactured by Kasano Kosan Co., Ltd., SP value 22.4).

According to the present invention, if the acrylic equivalent Cₐₑ of the active energy ray-curable adhesive composition represented by the following formula (1) is 140 or more, the cure shrinkage can be suppressed when the active energy ray-curable adhesive composition is cured, which improves the adhesive property of the active energy ray-curable adhesive composition to an adherend, that is specifically an polarizer.

Cₐₑ=1/Σ(W_{N}/Nₐₑ) (1)

In the formula (1), W_{N} represents a mass fraction of an active energy ray-curable compound N in the composition, and Nₐₑ represents an acrylic equivalent of the active energy ray-curable compound N. The reason why the adhering force of the adhesive layer increases when the acrylic equivalent of the active energy ray-curable adhesive composition is a prescribed value or more can be presumed as below.

The higher the value of the acrylic equivalent of the active energy ray-curable adhesive composition is, further the volume shrinkage is suppressed that is caused by the covalent bonds formed when the composition is irradiated with the active energy rays and cured. Herewith, the stress built at the interface between the adhesive layer and the adherend can be relaxed. As a result, the adhering force of the adhesive layer is improved.

The acrylic equivalent Cₐₑ is more preferably 155, and further more preferably 165 or more. In the present invention, the acrylic equivalent Cₐₑ is defined as follows.

(Acrylic Equivalent)=(Molecular Weight of Acrylic Monomer)/(Number of(meth)acryloyl groups in one acrylic monomer molecular)

The active energy ray-curable adhesive composition may contain an acrylic oligomer (D) obtained by polymerizing a (meth)acrylic monomer in addition to the active energy ray-curable compounds (A), (B), and (C) as curable components. If the active energy ray-curable adhesive composition contains the (D) component, the volume shrinkage is reduced when the composition is irradiated with the active energy rays and interface stress can be reduced between the adhesive layer and the adherend such as a polarizer and a transparent protective film. As a result, the deterioration of the adhesive property between the adhesive layer and the adherend can be suppressed. In order to sufficiently suppress the cure shrinkage of the cured layer (adhesive layer), the content of the acrylic oligomer (D) is preferably 3.0% by weight and more preferably 5.0% by weight. On the other hand, if the content of the acrylic oligomer (D) in the active energy ray-curable adhesive composition is too high, the reaction speed decreases rapidly when the composition is irradiated with the active energy rays, and curing may be uncompleted. Therefore, the content of the acrylic oligomer (D) in the active energy ray-curable adhesive composition is preferably 25% by weight or less and more preferably 15% by weight or less.

If the workability and the uniformity of coating of the active energy ray-curable adhesive composition is considered, the active energy ray-curable adhesive composition preferably has a low viscosity. Therefore, the acrylic oligomer obtained by polymerizing a (meth)acrylic monomer preferably has a low viscosity as well. The weight average molecular weight (Mw) of the acrylic oligomer which has a low viscosity and can prevent the cure shrinkage of the adhesive layer is preferably 15,000 or less, more preferably 10,000 or less, and especially preferably 5,000 or less. On the other hand, in order to sufficiently suppress the cure shrinkage of the cured layer (adhesive layer), the weight average molecular weight (Mw) of the acrylic oligomer (D) is preferably 500 or more, more preferably 1,000 or more, and especially preferably 1,500 or more. Specific examples of the (meth)acrylic monomer constituting the acrylic oligomer (D) include alkyl (meth)acrylate (1 to 20 carbon atoms) compounds such as methyl(meth)acrylate, ethyl(meth)acrylate, N-propyl(meth)acrylate, isopropyl(meth)acrylate, 2-methyl-2-nitrilepropyl(meth)acrylate, N-butyl(meth)acrylate, isobutyl(meth)acrylate, S-butyl(meth)acrylate, T-butyl(meth)acrylate, N-pentyl(meth)acrylate, T-pentyl(meth)acrylate, 3-pentyl(meth)acrylate, 2,2-dimethylbutyl(meth)acrylate, N-hexyl(meth)acrylate, cetyl(meth)acrylate, N-octyl(meth)acrylate, 2-ethylhexyl(meth)acrylate, 4-methyl-2-propylpentyl(meth)acrylate, and N-octadecyl(meth)acrylate; cycloalkyl(meth)acrylate such as cyclohexyl(meth)acrylate and cyclopentyl(meth)acrylate; aralkyl(meth)acrylate such as benzyl(meth)acrylate; polycyclic(meth)acrylate such as 2-isobonyl(meth)acrylate, 2-norbonylmethyl(meth)acrylate, 5-norbonene-2-i1-methyl(meth)acrylate, and 3-methyl-2-norbonylmethy(meth)acrylate; hydroxyl group-containing (meth)acrylate compounds such as hydroxyethyl(meth)acrylate, 2-hydroxypropyl(meth)acrylate, and 2,3-dihydroxypropylmethyl-butyl(meth)acrylate; alkoxy group or phenoxy group-containing (meth)acrylate compounds such as 2-methoxyethyl(meth)acrylate, 2-ethoxyethyl(meth)acrylate, 2-methoxymethoxyethyl(meth)acrylate, 3-methoxybutyl(meth)acrylate, ethylcarbitol(meth)acrylate, and phenoxyethyl(meth)acrylate; epoxy group-containing (meth)acrylate compounds such as glycidyl(meth)acrylate; halogen-containing (meth)acrylate compounds such as 2,2,2-trifluoroethyl(meth)acrylate, 2,2,2-trifluoroethylethyl(meth)acrylate, tetrafluoropropyl(meth)acrylate, hexafluoropropyl(meth)acrylate, octafluoropentyl(meth)acrylate, and heptadecafluorodecyl(meth)acrylate; and alkylaminoalkyl(meth)acrylate such as dimethylaminoethyl(meth)acrylate. The (meth)acrylate described above may be used either one type or in combination of two or more types. Specific examples of the acrylic oligomer (D) include “ARUFON” manufactured by TOAGOSAI CO., LTD., “ACTFLOW” manufactured by Soken Chemical & Engineering Co., Ltd., and “JONCRYL” manufactured by BASF Japan Ltd.

The active energy ray-curable adhesive composition preferably contains a radical polymerization initiator (E) having a hydrogen extraction effect. According to this configuration, the adhesive property of the adhesive layer of the polarizing film is remarkably improved especially even right after the polarizing film is removed from a highly humidified environment or water (non-dried state). The reason is not known. However, the following cause may be considered. If there is the radical polymerization initiator (E) having a hydrogen extraction effect in the active energy ray-curable adhesive composition, the active energy ray-curable compound is polymerized to form a base polymer which constitutes an adhesive layer, and a hydrogen is extracted from the methylene group, etc. of the active energy ray-curable compound to generate a radical. The methylene group, etc. in which the radical is generated reacts with a hydroxyl group of the polarizer such as PVA to form a covalent bond between the adhesive layer and the polarizer. As a result, especially even when the polarizing film is not dried, it is presumed that the adhesive property of the adhesive layer of the polarizing film is remarkably improved.

According to the present invention, examples of the radical polymerization initiator (E) having a hydrogen extraction effect include a thioxanthone-based radical polymerization initiator and a benzophenone-based radical polymerization initiator. An example of the thioxanthone-based radical polymerization initiator includes a compound represented by the following formula (2).

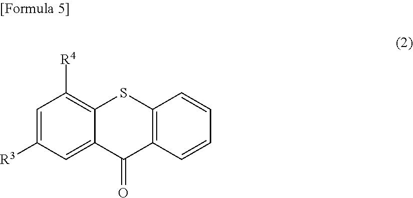

(In the formula, R³ and R⁴ represent —H, —CH₂CH₃, -iPr or Cl; R³ and R⁴ may be the same or different from one another.)

When the compound represented by the formula (2) is used, an excellent adhesive property can be achieved in comparison with a case of using a photopolymerization initiator alone which is highly sensitive to the light with a wavelength of 380 nm or more. The photopolymerization initiator which is highly sensitive to the light with a wavelength of 380 nm or more will be explained later. Among the compounds represented by the formula (2), diethylthioxanthone in which R³ and R⁴ are —CH₂CH₃ is especially preferable.

Because the photopolymerization initiator presented by the formula (2) can initiate polymerization by the long-wavelength light which is penetrating the transparent protective film having the ability of absorbing ultraviolet rays, the adhesive can be cured even over an ultraviolet ray-absorbing film. Specifically, even when a transparent protective film having the ability of absorbing ultraviolet rays is laminated on both sides of the polarizer, e.g., tiacetyl cellulose-polarizer-triacetyl cellulose, the adhesive composition can be cured if the photopolymerization initiator presented by the formula (2) is used.

The composition ratio of the radical polymerization initiator (E) having a hydrogen extraction effect, especially the composition ratio of the compound represented by the formula (2), is preferably 0.1% by weight to 10% by weight and more preferably 0.2% by weight to 5% by weight on the basis of 100% by weight of the total amount of the composition.

A polymerization initiating auxiliary is preferably added if necessary. Examples of the polymerization initiating auxiliary include trimethylamine, diethylamine, N-methyldiethanolamine, ethanolamine, 4-dimethylaminobenzoic acid, methyl 4-dimethylaminobenzoate, ethyl 4-dimethylaminobenzoate, and isoamyl 4-dimethylaminobenzoate; and especially ethyl 4-methylaminobenzoate is preferable. When the polymerization initiating auxiliary is used, the adding amount of the polymerization initiating auxiliary is normally 0% by weight to 5% by weight, preferably 0% by weight to 4% by weight, and most preferably 0% by weight to 3% by weight on the basis of 100% by weight of a total amount of the composition.

A known photopolymerization initiator can be also used if necessary. Because the transparent protective film having the ability of absorbing ultraviolet rays does not transmit the light with a wavelength of 380 nm or less, a photopolymerization initiator which is highly sensitive to the light with a wavelength of 380 nm or more is preferably used as the photopolymerization initiator. Specific examples include 2-methyl-1-(4-methylthiophenyl)-2-morpholinopropane-1-one, 2-benzyl-2-dimethylamino-1-(4-morpholinophenyl)-butanone-1,2-(dimethyl)-2-[(4-methylphenyl)methyl]-1-[4-(4-morpholnyl)phenyl]-1-butanone, 2,4,6-trimethylbenzoyl-diphenyl-phosphine oxide, bis(2,4,6-trimethylbenzoyl)-phenylphosphine oxide, and bis(H5-2,4-cyclopentadiene-1-yl)-bis(2,6-difluoro-3-(1H-pyrrole-1-yl)-phenyl)titanium.

In addition to the photopolymerization initiator represented by the formula (2), the compound represented by the following formula (3),

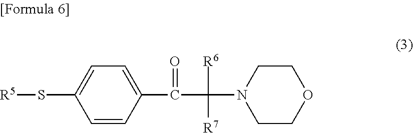

(In the formula, R³ and R⁴ represent —H, —CH₂CH₃, -iPr or Cl; R³ and R⁴ may be the same or different from one another) is especially preferably contained. The photopolymerization initiators represented by the formulas (2) and (3) are used together to increase the reaction efficiency due to the light sensitizing reaction of these initiators and to especially improve the adhesive property of the adhesive layer.

The active energy ray-curable adhesive composition preferably contains an active energy ray-curable compound having an active methylene group along with the radical polymerization initiator (E) having a hydrogen extraction effect. According to this configuration, the adhesive property of the adhesive layer of the polarizing film improves further.

The active energy ray-curable composition having an active methylene group has an active double bond group such as a (meth)acryl group at the end of the chain or in the molecule and the active energy ray-curable composition also has an active methylene group. Examples of the active methylene group include an acetoacetyl group, an alkoxymalonyl group, and a cyanoacetyl group. Specific examples of the active energy ray-curable compound include acetoacetoxyalkyl (meth)acrylate such as 2-acetoacetoxyethyl (meth)acrylate, 2-acetoacetoxypropyll (meth)acrylate, and 2-acetoacetoxy-1-methylethyl (meth)acrylate; 2-ethoxymalonyloxyethyl (meth)acrylate; 2-cyanoacetoxyethyl (meth)acrylate; N-(2-cyanoacetoxyethyl)acrylamide; N-(2-propionylacetoxybutyl)acrylamide; N-(4-acetoacetoxymethylbenzyl)acrylamide; and N-(2-acetoacetylaminoethyl)acrylamide. The SP value of the active energy ray-curable compound having an active methylene group is not especially limited, and a compound having an arbitrary value of the SP value can be used.

### <Photoacid Generator>

The active energy ray-curable compound can contain a photoacid generator. When the active energy ray-curable compound contains a photoacid generator, the water resistance and the durability of the adhesive layer can be remarkably improved in comparison with a case of the active energy ray-curable compound not containing a photoacid generator. A photoacid generator can be represented by the following formula (4).

### Formula (4)

L⁺·X⁻. [Formula 7]

(wherein, L⁺ represents an arbitrary onium cation, and X⁻ represents a counter anion selected from a group consisting of PF₆⁻, SbF₆⁻, AsF₆⁻, SbCl₆⁻, SnCl₆⁻, ClO₄⁻, a dithiocarbamate anion, and SCN⁻.)

The counter anion X⁻ in the formula (4) will be explained next.

The counter anion X⁻ represented by the formula (4) is not especially limited in principle. However, the counter anion X⁻ represented by the formula (4) is preferably a non-nucleophilic anion. When the counter anion X⁻ is a non-nucleophilic anion, a nucleophilic reaction hardly occurs with the cations and the various types of materials in the molecule. As a result, it is possible to improve the stability with time of the photoacid generator represented by the formula (4) and the composition in which the photoacid generator is used. The non-nucleophilic anion here indicates an anion having a poor ability to produce a nucleophilic reaction. Examples of the non-nucleophilic anion include PF₆⁻, SbF₆⁻, SbCl₆⁻, BiCl₅⁻, SnCl₆⁻, ClO₄⁻, a dithiocarbamate anion, and SCN⁻.

Preferred specific examples of the photoacid generator according to the present invention are “CYRACURE UVI-6992” and “CYRACURE UVI-6974” (manufactured by Dow Chemical Japan Ltd); “Adeka Optomer SP 150”, “Adeka Optomer SP 152”, Adeka Optomer SP 170″, and “Adeka Optomer SP 172” (manufactured by ADEKA CORPORATION); “IKAGACURE 250” (manufactured by Ciba Specialty Chemicals Inc.); “CI-5102” and “CI-2855” (manufactured by NIPPON SODA CO., Ltd.); “SAN-AID SI-60L”, “SAN-AID SI-80L”, “SAN-AID SI-100L”, “SAN-AID SI-110L”, and “SAN-AID SI-180L” (manufactured by SANSHIN CHEMICAL INDUSTRY CO., LTD.); “CPI-100P” and “CPI-100A” (manufactured by San-Apro Ltd.); and “WPI-069”, “WPI-113”, “WPI-116”, “WPI-041”, “WPI-044”, “WPI-054”, “WPI-055”, “WPAG-281”, “WPAG-567”, and “WPAG-596” (manufactured by Wako Pure Chemical Corporation).

The content of the photoacid initiator is 10% by weight or less, preferably 0.01% by weight to 10% by weight, more preferably 0.05% by weight to 5% by weight, and especially preferably 0.1% by weight to 3% by weight to the total amount of the composition.

### <Compound Containing any of Alkoxy Groups and Epoxy Groups>

A compound containing any of alkoxy groups and epoxy groups can be used with the photoacid generator in the active energy ray-curable adhesive composition.

### (Compound and Polymer Having Epoxy Groups)

When a compound having one or more epoxy groups in the molecule or a polymer having two or more epoxy groups in the molecule (epoxy resin) is used, a compound having two or more functional groups having reactivity with an epoxy group in the molecule may also be used. Examples of the functional group having reactivity with an epoxy group include a carboxyl group, a phenolic hydroxyl group, a mercapto group, and a primary or secondary aromatic amino group. Considering three-dimensional curing properties, two or more of these functional groups are especially preferably contained per molecule.

An example of the polymer having one or more epoxy groups in the molecule includes an epoxy resin. Examples of the epoxy resin include a bisphenol A-type epoxy resin derived from bisphenol A and epichlorohydrin, a bisphenol F-type epoxy resin derived from bisphenol F and epichlorohydrin, a bisphenol S-type epoxy resin, a phenol novolak-type epoxy resin, a cresol novolak-type epoxy resin, a bisphenol A novolak-types epoxy resin, a bisphenol F novolak-type epoxy resin, an alicyclic epoxy resin, a diphenylether-type epoxy resin, a hydroquinone-type epoxy resin, a naphthalene-type epoxy resin, a biphenyl-type epoxy resin, a fluorene-type epoxy resin, a multifunctional epoxy resin such as a tri-functional epoxy resin and a tetra-functional epoxy resin, a glycidylamine-type epoxy resin, a hydantoin-type epoxy resin, an isocyanurate-type epoxy resin, and a aliphatic chain epoxy resin. These epoxy resins may be halogenated or hydrogenated. Examples of the epoxy resin product which is commercially available include jER 828, 1001, 801N, 806, 807, 152, 604, 630, 871, YX8000, YX8034, and YX4000 manufactured by Japan Epoxy Resin Co.; EPICLON 830, EXA835LV, HP4032D, and HP820 manufactured by DIC CORPORATION; EP4100 series, EP4000 series, and EPU series manufactured by ADEKA CORPORATION; CELLOXIDE series (2021, 2021P, 2083, 2085, 3000, etc.), EPOLEAD series, EHPE series manufactured by DAICEL CORPORATION, YD series, YDF series, YDCN series, YDB series, a phenoxy resin which is polyhydroxypolyether synthesized from bisphenol and epichlorohydrin and has an epoxy group on both ends (YP series, etc.); DENACOL series manufactured by Nagase ChemteX Corporation; and Epolite series manufactured by KYOEISHA CHEMICAL Co., Ltd. However, the epoxy resin is not limited to these. Two or more types of these epoxy resins may be used together.

### (Compound and Polymer Having Alkoxyl Groups)

A compound having alkoxyl groups is not especially limited as long as it is a compound having one or more alkoxyl groups in the molecule and a known compound having alkoxyl groups in the molecule. Typical examples of the compound include a melamine compound, an amino resin, and a silane coupling agent.

The compounding amount of the compound containing any of alkoxy groups and epoxy groups is normally 30% by weight or less to the total amount of the composition. If the content of the compound in the composition is too high, the adhesive property deteriorates and the shock resistance during a drop test may deteriorate. The content of the compound in the composition is more preferably 20% by weight or less. On the other hand, from a point of the water resistance, the composition preferably contains 2% by the weight or more of the compound and more preferably 5% by weight or more of the compound.

### <Silane Coupling Agent>

A silane coupling agent having a Si—O bond can be used especially without limitation. However, a specific example of the silane coupling agent is an active energy ray-curable organic silicon compound or an organic silicon compound which is not active energy ray-curable. Especially, an organic silicon compound with an organic group having three or more carbon atoms is preferable. Examples of the active energy ray-curable compound include vinyltrichlorosilane, vinyltrimethoxysilane, vinyltriethoxysilane, 2-(3,4-epoxyxyclohexyl)ethyltrimethoxysilane, 3-glycidoxypropyltrimethoxysilane, 3-glycidoxypropylmethyldiethoxysilane, p-styryltrimethoxysilane, 3-methacyloxypropylmethyldimethoxysilane, 3-methacryloxypropyltrimethoxysilane, 3-methacryloxypropylmethyldiethoxysilane, 3-methacryloxypropyltriethoxysilane, and 3-acryloxypropyltrimethoxysilane.

The silane coupling agent is preferably 3-methacryloxypropyltrimethoxysilane or 3-acryloxypropyltrimethoxysilane.

A specific example of the compound which is not active energy ray-curable is a compound having an amino group. Specific examples of the compound having an amino group are amino group-containing silane compounds such as γ-aminopropyltrimethoxysilane, γ-aminopropyltriethoxysilane, γ-aminopropyltriisopropoxysilane, γ-aminopropylmethyldimethoxysilane, γ-aminopropylmethyldiethoxysilane, γ-(2-aminoethyl)aminopropyltrimethoxysilane, γ-(2-aminoethyl)aminopropylmethyldimethoxysilane, γ-(2-aminoethyl)aminopropyltriethoxysilane, γ-(2-aminoethyl)aminopropylmethyldiethoxysilane, γ-(2-aminoethyl)aminopropyltriisoproxysilane, γ-(2-(2-aminoethyl)aminoethyl)aminopropyltrimethoxysilane, γ-(6-aminohexyl)aminopropyltrimethoxysilane, 3-(N-ethylamino)-2-methylpropyltrimethoxysilane, γ-ureidepropyltrimethoxysilane, γ-ureidepropyltriethoxysilane, N-phenyl-γ-minopropyltrimethoxysilane, N-benzyl-γ-aminopropyltrimethoxysilane, N-vinylbenzyl-γ-aminopropyltrimethoxysilane, N-cyclohexylaminomethyltriethoxysilane, N-cyclohexylaminomethyldiethoxymethylsilane, N-phenylaminomethyltrimethoxysilane, (2-aminoethyl)aminomethyltrimethoxysilane, and N,N′-bis[3-(trimethoxyl)propyl]ethylenediamine; and ketamine-type silane compounds such as N-(1,3-dimethylbutylidene)-3-(triethoxysilyl)-1-propaneamine.

The compounds having an amino group may be used either one type or in combination of two or more types. Among these, in order to secure a good adhesive property, γ-aminopropyltrimethoxysilane, γ-(2-aminoethyl)aminopropyltrimethoxysilane, γ-(2-aminoethyl)aminopropylmethyldimethoxysilane, γ-(2-aminoethyl)aminopropyltriethoxysilane, γ-(2-aminoethyl)aminopropylmethyldiethoxysilane, and N-(1,3-dimethylbutylidene)-3-(triethoxysilyl)-1-propaneamine.

Other specific examples of the compound which is not active energy ray-curable include 3-ureidepropyltriethoxysilane, 3-chloropropyltrimethoxysilane, 3-mercaptopropylmethyldimethoxysilane, 3-mercaptopropyltrimethoxysilane, bis(triethoxysilylpropyl)tetrasulfide, 3-isocyanatepropyltriathoxysilane, and imidazolsilane.

The compounding amount of the silane coupling agent is preferably in the range of 0.01% by weight to 20% by weight, preferably 0.05% by weight to 15% by weight, and further preferably 0.1% by weight to 10% by weigh to the total amount of the curable resin composition. When the compounding amount of the silane coupling agent exceeds 20% by weight, the storage stability of the curable resin composition deteriorate. When the compounding amount of the silane coupling agent is less than 0.1% by weight, the effect of the adhesion water resistance cannot be sufficiently exhibited.

### <Compound Having Vinylether Groups>

The active energy ray curable-adhesive composition used in the present invention preferably contains a compound having vinylether groups because the adhesion water resistance between the polarizer and the adhesive layer improves. The reason why the effect describe above can be obtained is not clear. However, one of the reasons is assumed that the vinylether groups in the compound interact with the polarizer to increase the adhering force between the polarizer and the adhesive layer. In order to further increase the adhering force between the polarizer and the adhesive layer, the compound is preferably an active energy ray-curable compound having vinylether groups. The content of the compound is preferably 0.1% by weight to 19% by weight to the total amount of the curable resin composition.

<Additives Other than the Compounds Described Above>

Various types of additives can be compounded in the curable resin composition used in the present invention within the range of the objective and effect of the present invention. Examples of the additives include a polymer or an oligomer such as an epoxy resin, polyamide, polyamideimide, polyurethane, polybutadiene, polychloroplene, polyether, polyester, a styrene-butadiene block copolymer, a petroleum resin, a xylene resin, a ketone resin, a cellulose resin, a fluorine-containing oligomer, a silicone-containing oligomer, and a polysulfide-containing oligomer; a polymerization inhibitor such as phenothiazine and 2,6-di-t-butyl-4-mrthylphenol; a polymerization initiating auxiliary; a leveling agent; a wetting properties-improving agent; a surfactant; a plasticizer; an ultraviolet absorber; an inorganic filler; a pigment; and a dye.

The content of the additive is normally 0% by weight to 10% by weight, preferably 0% by weight to 5% by weight, and most preferably 0% by weight to 3% by weight.

### <Adhesive Layer>

The thickness of the adhesive layer formed by the active energy ray-curable adhesive composition is preferably 0.01 μm to 3.0 μm. When the thickness of the adhesive layer is too small, a cohesive force of the adhesive layer becomes insufficient and a peel force decreases. Therefore, the thickness of the adhesive layer is preferably not too small. When the thickness of the adhesive layer is too large, peeling can easily occur when a stress is applied onto the cross-section of the polarizing film and peeling defects due to the shock are generated. Therefore, the thickness of the adhesive layer is preferably not too large. The thickness of the adhesive layer is more preferably 0.1 μm to 2.5 μm and most preferably 0.5 μm to 1.5 μm.

### <Transparent Protective Film>

In the present invention, a cellulose-based resin film is used as a transparent protective film. The cellulose-based resin film means a film containing cellulose ester such as cellulose acetate as the main component. The cellulose-based resin film is manufactured from cellulose ester alone or with other polymer components if necessary as raw materials by a melt extrusion method. The “main component” means that the resin film contains 50% by weight or more of cellulose ester. From a viewpoint of improving the crack resistance of the polarizing film, a cellulose-based resin film containing 50% by weight or more of cellulose ester and especially a cellulose-based resin film containing 70% by weight or more of cellulose ester are preferably used as the transparent protective film. Acetyl cellulose obtained by reacting a natural cellulose polymer with anhydrous acetic acid and substituting a hydroxyl group (OH—) in the cellulose molecule with an acetyl group (CH₃CO—) (acetylation). Especially, TAC (triacetyl cellulose) obtained by acetylating all hydroxyl groups is preferably used.

A phase-difference cellulose-based resin film may be used as the transparent protective film in the present invention. In this case, the transparent protective film also serves as a phase difference film and the thickness of the polarizing film can be reduced. Therefore, the phase-difference cellulose-based resin film is preferable. The phase-difference cellulose-based resin film is also manufactured from cellulose ester alone or with other polymer components if necessary as raw materials by a melt extrusion method. The types of the substituents and the degree of substitution of lower fatty acid in cellulose ester can be modified to control the phase difference of the phase difference film that is obtained. In order to control the phase difference, a phase difference improver and a phase difference controller can be added. Cellulose ester described above can be manufactured with any suitable method such as a method disclosed in JP-A-2001-188128. Many products of cellulose ester are commercially available and cellulose ester is advantageous in the viewpoints of high availability and cost. Examples of cellulose ester that is commercially available include “UV-50”, “UV-80”, “SH-80”, TD-80U″, “TD-TAC”, and “UZ-TAC” manufactured by FUJIFILM Corporation; and “KC Series” manufactured by Konica Minolta, Inc.

When the cellulose ester described above contains an acetyl group as a substituent of lower fatty acid, the degree of substitution of an acetyl group is preferably 3 or less, further preferably 0.5 to 3, and especially preferably 1 to 3. When the cellulose ester described above contains a propionyl group as a substituent of lower fatty acid, the degree of substitution of a propionyl group is preferably 3 or less, further preferably 0.5 to 3, and especially preferably 1 to 3. When the cellulose ester described above is mixed fatty acid ester in which a portion of the hydroxyl groups in cellulose is substituted with an acetyl group and another portion of the hydroxyl groups is substituted with a propionyl group, a total of the degree of substitution of an acetyl group and the degree of substitution of a propionyl group is preferably 1 to 3 and further preferably 2 to 3. In this case, the degree of substitution of an acetyl group is preferably 0.5 to 2.5 and the degree of substitution of a propionyl group is preferably 0.3 to 1.5.

The degree of substitution of an acetyl group (or the degree of substitution of a propionyl group) is how many hydroxyl groups each attached to a carbon atom in 2-, 3-, or 6-position of the cellulose skeleton are substituted with an acetyl group (or a propionyl group). The acetyl groups (or the propionyl groups) may be non-uniformly or uniformly substituted with any of the hydroxyl group in 2-, 3-, or 6-position of the cellulose skeleton. The degree of substitution of an acetyl group can be obtained by following ASTM-D817-91 (a test method for cellulose acetate). The degree of substitution of a propionyl group can be obtained by following ASTM-D817-96 (a test method for cellulose acetate).

The weight average molecular weight (Mw) of the cellulose ester measured with a gel permeation chromatography (GPC) method by using tetrahydrofuran as a solvent is preferably 30,000 to 500,000, further preferably 50,000 to 400,000, and especially preferably 80,000 to 300,000. If the weight average molecular weight of the cellulose ester is within the above-described range, cellulose ester can be obtained with an excellent mechanical strength, a good solubility, a good formability, and a good operability in flow casting.

The molecular weight distribution (weight average molecular weight M_{w}/number average molecular weight Mₙ) of the cellulose ester is preferably 1.5 to 5.5 and further preferably 2 to 5.

The phase-difference cellulose-based resin film preferably satisfies the relationship nx>ny>nz. The in-plane phase difference of the phase-difference cellulose-based resin film is normally controlled to be in the range of 40 nm to 300 nm, and the phase difference in the thickness direction is normally controlled to be 80 nm to 320 nm. The in-pane phase difference is preferably 40 nm to 100 nm and the phase difference in the thickness direction is preferably 100 nm to 320 nm. A coefficient Nz preferably is 1.8 to 4.5. The coefficient Nz is typically about 3.5 to 4.5. According to the phase-difference cellulose-based resin film, view angle characteristics in a diagonal view direction can be improved. Especially, the phase-difference cellulose-based resin film is preferably applied to a liquid crystal display of an IPS mode or a VA mode. The coefficient Nz is represented by Nz=(nx−nz)/(nx−ny) (the definitions of nx, ny, and nz are same in the in-plane phase difference and the phase difference in the thickness direction).

An example of the phase-difference cellulose-based resin film is a biaxial phase difference film satisfying the relationship of refractive indexes nx>ny>nz such as “WVBZ4A6” and “WVBZ4E4” manufactured by FUJIFILM Corporation and “KC4DR-1” manufactured by Konica Minolta, Inc. The polymer film containing cellulose ester is uniaxially or biaxially stretched in a longitudinal direction or a lateral direction to control the phase difference.

The phase-difference cellulose-based resin film may have a proper phase difference in accordance with the purpose of use such as a use for compensating a viewing angle and a coloring due to the birefringence from various types of the wavelength plates and liquid crystal layers. Two types or more of the phase-difference cellulose-based resin films are laminated to control the optical characteristics such as a phase difference.

The transparent protective film may contain one type or more of any suitable additives. Examples of the additives include an ultraviolet absorber, an antioxidant, a lubricant, a plasticizer, a mold releasing agent, a coloring inhibitor, a flame retardant, a nucleating agent, an antistatic agent, a pigment, and a coloring agent. The content of the additives in the transparent protective film is preferably 0% by weight to 50% by weight, more preferably 1% by weight to 50% by weight, further preferably 2% by weight to 40% by weight, and especially preferably 3% by weight to 30% by weight. If the amount of the additives in the transparent protective film exceeds the above-described range, high transparency of the transparent protective film may not be sufficiently exhibited.

According to the polarizing film in the present invention, the transparent protective film may be provided only on one side of the polarizer through the adhesive layer or on both sides of the polarizer through an adhesive layer. In the former case, the cellulose-based resin film is used as the transparent protective film. On the other hand, in the latter case, it is necessary to laminate the cellulose-based resin film on one side of the polarizer as the transparent protective film through the adhesive layer. However, on another side of the polarizer, the cellulose-based resin film may be laminated as the transparent protective film or a resin film other than the cellulose-based resin film may be laminated as the transparent protective film.

The transparent protective film that can be used other than the cellulose-based resin film preferably has excellent transparency, mechanical strength, thermal stability, moisture shielding properties, and isotropy. Examples include a polyester-based polymer such as polyethylene terephthalate and polyethylene naphtalate, an acrylic polymer such as polymethylmethacrylate, a styrene-based polymer such as polystyrene and an acrylonitrile-styrene copolymer (AS resin), and a polycarbonate-based polymer. Other examples of the polymer forming the transparent protective film include polyethylene, polypropylene, cyclic polyolefin, polyolefin having a norborenene structure, a polyolefin-based polymer such as an ethylene-propylene copolymer, a vinylchloride-based polymer, an amide-based polymer such as nylon and aromatic polyamide, an imide-based polymer, a sulfone-based polymer, a polyether sulfone-based polymer, a polyetherether ketone-based polymer, a polyphenylene sulfide-based polymer, a vinylalcohol-based polymer, a vinylidene chloride-based polymer, a vinylbutyral-based polymer, an arylate-based polymer, a polyoxymethylene-based polymer, an epoxy-based polymer, and a bended compound of the polymers described above.

An examples of the transparent protective film that can be used other than the cellulose-based resin film is a polymer film disclosed in JP-A-2001-343529 (WO01/37007) such as a resin compound containing a thermoplastic resin with a substituted and/or non-substituted imide group on (A) a side chain and a thermoplastic resin with substituted and/or non-substituted phenyl and nitrile groups on a side chain. A specific example is a film of a resin composition containing an alternating copolymer consisting of isobutylene and N-methylmaleimide and an acrylonitrile-styrene copolymer. A film can be used formed from a mixed and extruded product of the resin composition. These films have a small phase difference and a small photoelastic coefficient. Therefore, problems such as unevenness due to the distortion of the polarizing film can be solved, and because the moisture permeability is small, the film has an excellent durability against moisture.

The thickness of the transparent protective film can be properly determined. In general, from the points of strength, processability such as handleability, thin layer properties, etc., the thickness of the transparent protective film is preferably 5 μm to 100 μm. Especially, the thickness of the transparent protective film is preferably 10 μm to 60 μm and more preferably 13 μm to 40 μm.

### <Polarizer>

In the present invention, from a viewpoint of improving the durability against the crack, a thin polarizer is preferably used having a thickness of 3 μm to 15 μm. Especially, from a viewpoint of suppressing the generation of a through crack in the polarizer, the thickness of the polarizer is preferably 12 μm or less further preferably 10 μm or less, and especially preferably 8 μm or less. The thin polarizer described above has less thickness unevenness and an excellent visibility, and because the dimensional change of the polarizer is small, the thin polarizer described above has an excellent durability against thermal shock.

A polyvinyl alcohol-based resin is used to form the polarizer. Examples of the polarizer include a polarizer formed by letting dichroic materials such as iodine and dichroic dye being absorbed in a hydrophilic polymer film such as a polyvinyl alcohol-based film, a partially-formalized polyvinyl alcohol-based film, and an ethylene-vinylacetate copolymer partially-saponified film and uniaxially stretching the hydrophilic polymer film; and a polyene-based oriented film such as a dehydrated product of polyvinyl alcohol and a dehydrated product of polyvinylchloride. Among these, a polarizer is preferable formed from a dichroic substance of a polyvinyl alcohol-based film and iodine.

A polarizer formed by coloring a polyvinyl alcohol-based polymer with iodine and uniaxially stretching the polyvinyl alcohol-based polymer can be manufactured by soaking polyvinyl alcohol in an aqueous solution of iodine to color and stretching the film at 3 times to 7 times of the initial length. The film may be soaked in an aqueous solution of boric acid, potassium iodide, etc. if necessary. The polyvinyl alcohol-based film may be washed by soaking the film in water before coloring if necessary. The polyvinyl alcohol-based film is washed with water to clean dirt and an antiblocking agent. In addition, the polyvinyl alcohol-based film is swollen during washing to prevent nonuniformity such as dyeing unevenness. The stretching may be performed after dyeing, while dyeing, or before dyeing with iodine. The polyvinyl alcohol-based film can be stretched in the aqueous solution of boric acid, potassium iodide, etc. or when the film is washed in water.

The polarizer preferably contains boric acid from the points of a stretching stability and a reliability under a humidified environment. From a viewpoint of suppressing the generation of a through crack in the polarizer, the content of boric acid in the polarizer is preferably 22% by weight or less and further preferably 20% by weight or less to the total amount of the polarizer. From the viewpoints of the stretching stability and the reliability under a humidified environment, the content of boric acid to the total amount of the polarizer is preferably 10% by weight or more and further preferably 12% by weight or more.

Typical examples of the thin polarizer are thin polarizer or thin polarizers obtained by the production methods disclosed in U.S. Pat. No. 4,751,486, Patent 4751481, Patent 4815544, Patent 5048120, International Patent 2014-077599, International Patent 2014-077636, etc.

From a viewpoint of being capable of stretching at high magnification to improve the polarization performance, among the production methods of the thin polarizing film including a step of stretching a laminate and a step of dyeing, the thin polarizing film is preferably obtained by the production method including a step of stretching in an aqueous solution of boric acid disclosed in U.S. Pat. Nos. 4,751,486, 4,751,481, or 4,815,544, and especially preferably obtained by the production method including a step of stretching in air secondarily before stretching in an aqueous solution of boric acid disclosed in U.S. Pat. Nos. 4,751,481 and 4,815,544. These thin polarizing films can be obtained by a production method including a step of stretching a laminate of a polyvinyl alcohol-based resin (below, also referred to as a PVA resin) layer and a resin base for stretching and a step of dyeing. According to this production method, the thin polarizing film can be stretched without a problem of rupture due to being stretched because the film is supported by the resin base for stretching even when the thickness of the PVA resin layer is small.

### <Easy Adhesive Layer>

According to the polarizing film of the present invention, the polarizer and the transparent protective film are laminated through the adhesive layer formed by the cured layer of the active energy ray-curable adhesive composition. However, an easy adhesive layer can be provided between the transparent protective film and the adhesive layer. For examples, the easy adhesive layer can be formed by various types of resin having a polyester skeleton, a polyether skeleton, a polycarbonate skeleton, a polyurethane skeleton, a silicone skeleton, a polyamide skeleton, a polyimide skeleton, or a polyvinyl alcohol skeleton. The polymer resin described above may be used either one type or in combination of two or more types. The additive may be added in the formation of the easy adhesive layer. Specific examples of the additive include a tackifier, an ultraviolet absorber, an antioxidant, and a stabilizer such as a heat-resistance stabilizer.

Normally, the easy adhesive layer is provided on the transparent protective film in advance, and the easy adhesive layer side of the transparent protective film and the polarizer are laminated through the adhesive layer. The transparent protective film is coated with a material for forming the easy adhesive layer by a known technique and the material is dried to form the easy adhesive layer. The material for forming the easy adhesive layer is normally prepared as a solution diluted to an appropriate concentration by considering the thickness after drying, the smoothness of coating, etc. The thickness of the easy adhesive layer after drying is preferably 0.01 μm to 5 μm, further preferably 0.02 μm to 2 μm, and further preferably 0.01 μm to 1 μm. A plurality of the easy adhesive layers may be provided. However, in this case, the total thickness of the easy adhesive layers is preferably within the above-described range.

The polarizing film according to the present invention may have a configuration in which the easy adhesive layer containing a specific boric acid group-containing compound is formed on at least one of the laminating sides of the polarizer and the transparent protective film and the polarizer and the transparent protective film are laminated through the adhesive layer. According to this configuration, the polarizing film can be provided having a good adhesive property of the polarizer and the transparent protective film with the adhesive layer and that is capable of keeping the adhering force even under a dew condensation environment or a harsh environment where the polarizing film is soaked in water.

Specifically, a compound represented by the following formula (1):

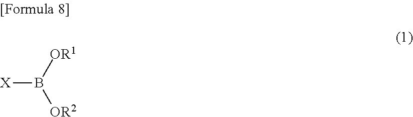

(wherein, X represents a functional group including a reactive group and R¹ and R² represent each independently a hydrogen atom, an aliphatic hydrocarbon group which may have a substituent, an aryl group which may have a substituent, or a heterocyclic group which may have a substituent) is provided on at least one of the laminating sides of the polarizer and the transparent protective film, and the compound represented by the formula (1) preferably lies between the polarizer and the adhesive layer and/or between the transparent protective film and the adhesive layer. Examples of the aliphatic hydrocarbon group are a straight-chain or branched alkyl group which may have a substituent having 1 to 20 carbon atoms, a cyclic alkyl group which may have a substituent having 3 to 20 carbon atoms, and an alkenyl group having 2 to 20 carbon atoms. Examples of the aryl group include a phenyl group which may have a substituent having 6 to 20 carbon atoms and a naphthyl group which may have a substituent having 10 to 20 carbon atoms. An examples of the heterocyclic group is a 5-membered ring or a 6-membered ring which contains at least one hetero atom and may have a substituent. These may be linked to each other to form a ring. R¹ and R² in the formula (1) are preferably a hydrogen atom having 1 to 3 carbon atoms and most preferably a hydrogen atom. The compound represented by the formula (1) may lies between the polarizer and the adhesive layer and/or between the transparent protective film and the adhesive layer in an unreacted state or a reacted state. “The compound represented by the formula (1) is provided on at least one of the laminating sides of the polarizer and the transparent protective film” means that at least one molecule of the compound represented by the formula (1) exists on the laminating side. However, in order to sufficiently improve the adhesion water resistance between the polarizer and the transparent protective film and the adhesive layer, an easy adhesive composition containing the compound represented by the formula (1) is used, and the easy adhesive layer is preferably formed at least a part of the laminating sides and more preferably on the entire laminating side.

In the embodiment below, a polarizing film will be explained in which the transparent protective film is laminated on at least one side of the polarizer through the adhesive layer and the easy adhesive layer formed by using the easy adhesive composition containing the compound represented by the formula (1) is provided on at least one of the laminating sides of the polarizer and the transparent protective film.

The X in the compound represented by the formula (1) is a functional group including a reactive group, and a functional group that can react with the curable component configuring the adhesive layer. Examples of the reactive group included in the X include a hydroxyl group, an amino group, a aldehyde group, a carboxyl group, a vinyl group, a (meth)acryl group, a steryl group, a (meth)acrylamide group, a vinylether group, an epoxy group, an oxetane group, an α,β-unsaturated carbonyl group, a mercapto group, and a halogen group. When the curable resin composition configuring the adhesive layer is an active energy ray-curable composition, the reactive group included in the X is preferably at least one type selected from a group consisting of a vinyl group, a (meth)acryl group, a steryl group, a (meth)acrylamide group, a vinylether group, an epoxy group, an oxetane group, and a mercapto group. Especially when the curable resin composition configuring the adhesive layer is a radical polymerizable composition, the reactive group included in the X is preferably at least one type selected from a group consisting of a (meth)acryl group, a steryl group, and a (meth)acrylamide group, and the compound represented by the formula (1) more preferably contains a (meth)acrylamide group because the rate of copolymerization of the compound to the active energy ray-curable resin composition increases. The (meth)acrylamide group is preferable also from a point of obtaining the effect of the present invention due to a high polarity and the excellent adhesive property of the (meth)acrylamide group. When the curable resin composition configuring the adhesive layer is a cation polymerizable composition, the reactive group included in the X is preferably at least one type selected from a group consisting of a hydroxyl group, an amino group, a aldehyde group, a carboxyl group, a vinylether group, an epoxy group, an oxetane group, and a mercapto group. The curable resin composition configuring the adhesive layer preferably contains an epoxy group because the obtained curable resin layer has an excellent adhesion with the adherend. The curable resin composition configuring the adhesive layer preferably contains a vinylether group because the curable resin composition has an excellent curing property with the adherend.

A specific example of the compound represented by the formula (1) is a compound represented by the following formula (1′),

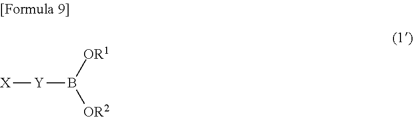

(wherein, Y represents an organic group; and X, R¹, and R² are the same as described above). Further preferable examples are the following compounds (1a) to (1d).

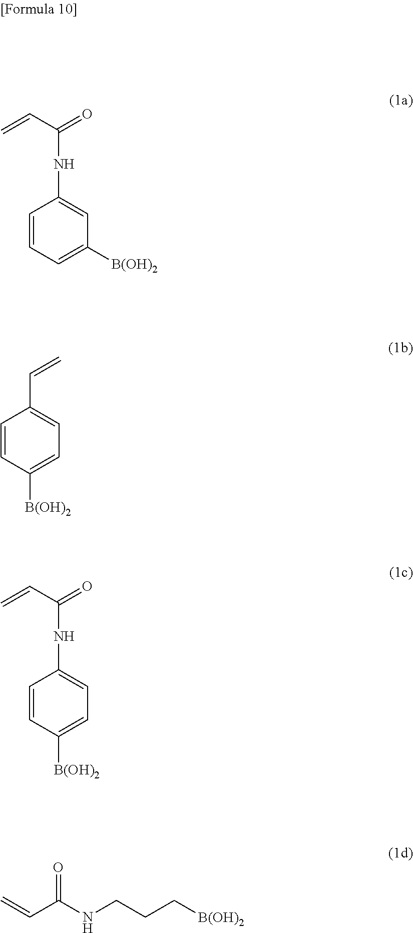

In the present invention, the compound represented by the formula (1) may consist of the reactive group which is directly bonded to the boron atom. However, as shown in the specific examples described above, the compound represented by the formula (1) preferably consists of the reactive group which is bonded to the boron atom through an organic group. That is, the compound represented by the formula (1) is preferably the compounds represented in the formula (1′). When the compound represented by the formula (1) consists of the reactive group which is bonded to the boron atom through the oxygen atom bonded to the boron atom, the adhesion water resistance of the polarizing film tends to deteriorate. On the other hand, the compound represented by the formula (1) preferably consists of the reactive group in which the boron atom and the organic group are bonded to each other with a boron-carbon bond not a boron-oxygen bond (Formula (1′)) because the adhesion water resistance of the polarizing film improves. Specifically, the organic group may have a substituent. The organic group means an organic group having 1 to 20 carbon atoms, and specific examples include a straight-chain or branched alkylene group which may have a substituent having 1 to 20 carbon atoms, a cyclic alkylene group which may have a substituent having 3 to 20 carbon atoms, a phenylene group which may have a substituent having 6 to 20 carbon atoms, and a naphthylene group which may have a substituent having 10 to 20 carbon atoms.

Other examples of the compound represented by the formula (1) are esters of (meth)acrylate and boric acid such as ester of hydroxyethylacrylamide and boric acid, ester of methylolacrylamide and boric acid, ester of hydroxyethylacrylate and boric acid, and ester of (meth)acrylate and boric acid.

According to the polarizing film of the present invention, the polarizer and the transparent protective film are laminated through the adhesive layer formed by the cured layer obtained by irradiating an active energy ray-curable adhesive composition with active energy rays. In the present invention, especially when the active energy ray-curable adhesive composition contains the acrylic oligomer (D), a compatible layer may be formed between the transparent protective film and the adhesive layer, where these layers change continuously. When the compatible layer is formed, the adhering force between the transparent protective film and the adhesive layer improves. However, the value of P×Q is preferably less than 10, where P(μm) represents the thickness of the compatible layer and Q (% by weight) represents the content of the acrylic oligomer (D) on the basis of 100% by weight of the total amount of the composition because the adhering force between the transparent protective film and the adhesive layer especially increases. On the other hand, if the content Q (% by weight) of the acrylic oligomer (D) is too large, the molecular weight of the acrylic oligomer (D) is large in general and when the compatible layer is formed between the adhesive layer and the transparent protective film, the acrylic oligomer (D) hardly penetrates to the transparent protective film side and the acrylic oligomer (D) unevenly distributed in the interface between the adhesive layer and the compatible layer, resulting the compatible layer become fragile. Because an adhesive failure can easily occur due to the fragile layer, the content of the acrylic oligomer is Q % by weight is preferably designed so that the value of P×Q is less than 10. If the compatibility between the adhesive layer and the transparent protective film becomes excessive and the thickness P (μm) of the compatible layer becomes too large, a portion of the compatible layer becomes fragile and the adhering force between the adhesive layer and the transparent protective layer easily decreases. Therefore, the thickness P (μm) of the compatible layer is preferably designed so that the value of P×Q is less than 10.

The polarizing film according to the present invention includes: a coating step of coating the active energy ray-curable adhesive composition on at least one of sides of a polarizer and a transparent protective film; a laminating step of laminating the polarizer and the transparent protective film; and an adhering step of adhering the transparent protective film to the polarizer through an adhesive layer obtained by irradiating the polarizer or the transparent protective film with active energy rays to cure the active energy ray-curable adhesive composition.

A surface modification treatment may be performed on the polarizer and the transparent protective film before the coating step. Especially, the surface modification treatment can be preferably performed on the surface of the polarizer. Examples of the surface modification treatment include a corona treatment, a plasma treatment, an excimer treatment, and a frame treatment, and especially preferably a corona treatment. The corona treatment is performed to produce reactive a functional group such as a carbonyl group and an amino group on the surface of the polarizer, and the adhesion of the polarizer to the curable resin layer improves. The impurities on the surface of the polarizer are removed due to the asking effect and the unevenness of the surface is decreased. As a result, a polarizing film with excellent appearance characteristics can be produced.

### <Coating Step>

The method for coating the active energy ray-curable adhesive composition can be appropriately selected depending on the viscosity of the composition and the desired thickness of the coating, and examples include a reverse coater, a gravure coater (direct, reverse, or offset), a reverse roll coater, a roll coater, a die coater, a bar coater, and a rod coater. The viscosity of the active energy ray-curable adhesive composition used in the present invention is preferably 3 mPa·s to 100 mPa·s, more preferably 5 mPa·s to 50 mPa·s, and most preferably 10 mPa·s to 30 mPa·s. When the viscosity of the composition is high, it is not preferable because the surface smoothness after coating is poor and the appearance failure occurs. The viscosity of the active energy ray-curable adhesive composition can be adjusted to a preferable range by heating or cooling the composition before coating.

### <Laminating Step>

The polarizer and the transparent protective film are laminated through the active energy ray-curable adhesive composition coated with the method described above. The lamination of the polarizer and the transparent protective film can be performed by a roll laminator, etc.

### <Adhering Step>

After laminating the polarizer and the transparent protective film, the active energy ray-curable adhesive composition is irradiated with active energy rays such as electron beams, ultraviolet rays, and visible rays to cure the active energy ray-curable adhesive composition and form an adhesive layer. The irradiation direction of the energy rays such as electron beams, ultraviolet rays, and visible rays can be adequately selected. Preferably, the transparent protective film is irradiated with the active energy rays. If the polarizer is irradiated with the active energy rays, the polarizer may be deteriorated due to the active energy rays such as electron beams, ultraviolet rays, and visible rays.

When using electron beams, the suitable conditions can be adopted as the irradiation conditions as long as the active energy ray-curable adhesive composition can be cured with the conditions. For example, the acceleration voltage of the electron beams is preferably 5 kV to 300 kV, and further preferably 10 kV to 250 kV. When the acceleration voltage is less than 5 kV, the electron beams do not reach the adhesive and curing may be insufficient. When the acceleration voltage exceeds 300 kV, the penetration of the electron beams into a sample is too strong and the transparent protective film and the polarizer may be damaged. The exposure dose is preferably 5 kGy to 100 kGy and further preferably 10 kGy to 75 kGy. When the exposure dose is less than 5 kGy, curing of the adhesive is insufficient. When the exposure dose exceeds 100 kGy, the transparent protective film and the polarizer are damaged, the mechanical strength deteriorates, and yellowing occurs. As a result, the predetermined optical characteristics cannot be achieved.

The irradiation with the electron beams is normally performed in an inert gas. If necessary, the irradiation with the electron beams can be performed in atmosphere or the condition where a small amount of oxygen is added. Depending on the raw materials consisting the transparent protective film, the addition of an appropriate amount of oxygen can create an oxygen inhibition on the surface of the transparent protective film where the electron beams hit first, which prevents damage of the transparent protective film, and only the adhesive can be effectively irradiated with the electron beams.

In case of manufacturing the polarizing film according to the present invention, the active energy rays are preferably active energy rays containing visible light of a wavelength range from 380 nm to 450 nm and especially preferably active energy rays having the largest exposure dose from the visible light rays of a wavelength range from 380 nm to 450 nm. When the ultraviolet rays and the visible light are used and a transparent protective film having the ability of absorbing ultraviolet rays (ultraviolet impermeable transparent protective film) is used, the film absorbs the light with the short wavelength less than about 380 nm. Therefore, the light with the short wavelength less than 380 nm does not reach the active energy ray-curable adhesive composition and the light with the short wavelength less than 380 nm does not contribute to the polymerization reaction. Further, the light with the short wavelength less than 380 nm absorbed by the transparent protective film is converted into heat and the transparent protective film generates heat by itself, which causes a defect of the polarizing film such as curls and winkles. Therefore, when the ultraviolet rays and the visible light are used in the present invention, an active energy ray generator is preferably used which does not emit the light with the short wavelength less than 380 nm. Specifically, the ratio of the integrated illuminance of the light with a wavelength range from 380 nm to 440 nm to the integrated illuminance of the light with a wavelength range from 250 nm to 370 nm is preferably 100:0 to 100:50 and more preferably 100:0 to 100:40. When manufacturing polarizing film according to the present invention, the source of the active energy rays is preferably a gallium-sealed metal halide lamp or an LED light source which emits the light with a wavelength range 380 nm to 440 nm. A low pressure mercury lamp, a medium pressure mercury lamp, a high pressure mercury lamp, a super high pressure mercury lamp, an incandescent bulb, a xenon lamp, a halogen lamp, a carbon arc light, a metal halide lamp, a fluorescent lamp, a tungsten lamp, a gallium lamp, an excimer lamp, or a light source containing ultraviolet rays and visible light such as sunlight may also be used, and a band path filter may be also used to shield the ultraviolet rays with the short wavelength less than 380 nm. In order to prevent curls of the polarizing film while improving the adhesive performance of the adhesive layer between the polarizer and the transparent protective film, the active energy rays obtained by using a gallium-sealed metal halide lamp with a band path filter which can shield the light with the short wavelength less than 380 nm or the active energy rays with a wavelength of 405 nm obtained by using a LED light source.

The active energy ray-curable adhesive composition is preferably heated before the ultraviolet ray or the visible light irradiation (heating before irradiation). In this case, the active energy ray-curable adhesive composition is preferably heated to 40° C. or higher and more preferably 50° C. or higher. The active energy ray-curable adhesive composition is preferably heated also after the ultraviolet ray or the visible light irradiation (heating after irradiation). In this case, the active energy ray-curable adhesive composition is preferably heated to 40° C. or higher and more preferably 50° C. or higher.

The active energy ray-curable adhesive composition used in the present invention is preferably used especially when forming an adhesive layer which adheres a polarizer and a transparent protective film in which the transmittance of the light with a wavelength 365 nm is less than 5%. The active energy ray-curable adhesive composition according to the present invention contains a photopolymerization initiator represented by the formula (2). The active energy ray-curable adhesive composition according to the present invention is irradiated with the ultraviolet rays through a transparent protective film having the ability of absorbing ultraviolet rays and cured to form an adhesive layer. Therefore, the adhesive layer can be cured in the polarizing film in which the transparent protective film having the ability of absorbing ultraviolet rays is laminated on both sides of the polarizer. As expected, the adhesive layer can be cured also in the polarizing film in which the transparent protective film not having the ability of absorbing ultraviolet rays is laminated. The transparent protective film having the ability of absorbing ultraviolet rays means a transparent protective film in which the permeability to light having a wavelength of 380 nm is less than 10%.

Examples of the method for giving the ability of absorbing ultraviolet rays to the transparent protective film are a method of mixing an ultraviolet absorber into the transparent protective film and a method of laminating a surface modification layer containing an ultraviolet absorber on the surface of the transparent protective film.

Specific examples of the ultraviolet absorber include a conventionally-known oxybenzophenone-based compound, a benzotriazole-based compound, a salicylate ester-based compound, a benzophenone-based compound, a cyanoacrylate-based compound, a nickel complex salt-based compound, and a triazine-based compound.

When manufacturing the polarizing film according to the present invention in a continuous line. The line speed depends on the curing time of the curable resin composition. However, the line speed is preferably 1 m/min to 500 m/min, more preferably 5 m/min to 300 m/min, and further preferably 10 m/min to 100 m/min. When the line speed is too small, the productivity becomes poor or the transparent protective film is largely damaged and a polarizing film that can endure a durability test, etc. cannot be produced. When the line speed is too large, the curing of the curable resin composition becomes insufficient and the objective adhesion may not be obtained.

The method for manufacturing the polarizing film according to the present invention may include an adhesion facilitating treatment step of forming an easy adhesive layer containing a specified boric acid-containing compound on at least one of the laminating sides of the polarizer and the transparent protective film before the coating step. Specifically, the polarizing film can be manufactured by the following method:

a method of a polarizing film in which a transparent protective film is laminated on at least one side of a polarizer through an adhesive layer and including an adhesion facilitating treatment step of attaching preferably the compound represented by the formula (1), more preferably the compound represented by the formula (1′), onto at least one of the laminating sides of the polarizer and the transparent protective film; a coating step of coating a curable adhesive composition on at least one of the sides of a polarizer and a transparent protective film; a step of laminating the polarizer and the transparent protective film; and an adhering step of adhering the transparent protective film to the polarizer through an adhesive layer obtained by irradiating the polarizer or the transparent protective film with active energy rays to cure the curable adhesive composition.

### <Adhesion Facilitating Treatment Step>

An examples of the method of forming an easy adhesive layer on at least one of the laminating sides of the polarizer and the transparent protective film by using an easy adhesive composition containing the compound represented by the formula (1) is a method of manufacturing an easy adhesive composition (A) containing the compound represented by the formula (1) and coating at least one of the laminating sides of the polarizer and the transparent protective film with the easy adhesive composition (A) to form an easy adhesive layer. Examples of the materials that may be contained in the easy adhesive composition (A) besides the compound represented by the formula (1) include a solvent and an additive.

When the easy adhesive composition contains a solvent, at least one of the laminating sides of the polarizer and the transparent protective film is coated with the easy adhesive composition (A) and a drying step or a curing treatment (thermal treatment) may be performed if necessary.

The solvent may be contained by the easy adhesive composition (A) is preferably a solvent that stabilizes the compound represented by the formula (1) and dissolves or disperses into the compound represented by the formula (1). An organic solvent, water, or the mixture of an organic solvent and water can be used as the solvent. Examples of the solvent include esters such as ethylacetate, butyl acetate, and 2-hydroxyethylacetate; ketones such as methyethylketone, acetone, cyclohexanone, methylisobutylketone, diethylketone, methyl-n-propylketone, and acetylacetone; cyclic ethers such as tetrahydrofuran (THF) and dioxane; aliphatic or alicyclic hydrocarbons such as n-hexane and cyclohexane; aromatic hydrocarbons such as toluene and xylene; aliphatic or alicyclic alcohols such as methanol, ethanol, n-propanol, isopropanol, and cyclohaxanol; glycol ethers such as ethylene glycol monomethylether, ethylene glycol monoethylether, and diethylene glycol monomethylether; and glycol ether acetates such as diethylene glycol monomethylether acetate and diethylene glycol monoethylether acetate.

Examples of the additive that may be contained by the easy adhesive composition (A) include a surfactant, a plasticizer, a tackifier, a low molecular weight polymer, a polymerizable monomer, a surface lubricant, a leveling agent, an antioxidant, a corrosion inhibitor, a photo stabilizer, an ultraviolet absorber, a polymerization inhibitor, a silane coupling agent, a titian coupling agent, an inorganic or organic filler, metal powders, a granular material, and a foil-state material.

When the easy adhesive composition (A) contains a polymerization initiator, the compound represented by the formula (1) may react in the easy adhesive layer before laminating the adhesive layer and the effect of improving the adhesion water resistance of the polarizing film, which is the primary objective of the present invention, may not be obtained sufficiently. Therefore, the content of the polymerization initiator in the easy adhesive layer is preferably less than 2% by weight, preferably less than 0.5% by weight, and especially preferably the easy adhesive layer does not contain the polymerization initiator.

If the content of the compound represented by the formula(1) in the easy adhesive layer is too small, the ratio of the compound represented by the formula (1) existing on the surface of the easy adhesive layer to the easy adhesive layer decreases and the effect of easy adhesion may be small. Therefore, the content of the compound represented by the formula(1) in the easy adhesive layer is preferably 1% by weight or more, more preferably 20% by weight or more, and further preferably 40% by weight or more.

A method of soaking a polarizer directly in a treatment bath of the composition (A) or a known coating method can be appropriately used as the method of forming the easy adhesive layer on a polarizer by using the easy adhesive composition (A). Specific examples of the coating method include a roll coating method, a gravure coating method, a reverse coating method, a roll brush coating method, a spray coating method, an air knife coating method, and a curtain coating method. However, the coating method is not limited to these.

In the present invention, the thickness of the easy adhesive layer on the polarizer is too large, a cohesive force of the easy adhesive layer decrease and the effect of easy adhesion may become small. Therefore, the thickness of the easy adhesive layer is preferably 2,000 nm or less, more preferably 1,000 nm or less, and further preferably 500 nm or less. On the other hand, the lowest limit of the thickness in which the effect of the easy adhesive layer can be exhibited sufficiently is a thickness of the monolayer of the compound represented by the formula (1); and the thickness of the easy adhesive layer is preferably 1 nm or more, more preferably 2 nm or more, and further preferably 3 nm or more.

### <Optical Film>

Practically, the polarizing film according to the present invention can be laminated to another optical layer and used as an optical film. The optical layer is not especially limited, and an example includes an optical layer which can be used to form a liquid crystal display device, etc. such as a phase difference film including a half or a quarter wavelength plate, a vision compensation film, a luminance improving film, a reflector, and a semi-transmission plate. These optical layers can be used as a base film of an easy adhesive layer-attached base film in the present invention. The surface modification treatment can be performed on these optical layers to allow these optical layers to have a reactive functional group such as a hydroxyl group, a carbonyl group, and an amino group. Therefore, an adhesion facilitated phase difference film and especially an easy adhesive layer-attached phase difference film, in which the compound represented by the formula (1) is provided on at least one side of the phase difference film at least containing a reactive functional group on the surface, are preferable because the adhesion between the adhesive layer and the phase difference film improves and the adhesive property especially improves.

A phase difference film having a front phase difference of 40 nm or more and/or a phase difference in the thickness direction of 80 nm or more can be used as the phase difference film. The front phase difference is normally controlled to be in a range of 40 nm to 200 nm and the phase difference in the thickness direction is normally controlled in a range of 80 nm to 300 nm.

Examples of the phase difference film include a birefringent film formed by monoaxially or biaxially stretching a polymer material, an oriented film of a liquid polymer, and an oriented layer of a liquid crystal polymer. The thickness of the phase difference film is not especially limited. However, the thickness of the phase difference film is generally about 20 μm to 150 μm.

As the phase difference film, a phase difference film of a reverse wavelength dispersion type may be used which satisfies the following formulas (1) to (3):(1) 0.70<Re[450]/Re[550]<0.97, (2) 1.5×10⁻³<Δn<6×10⁻³, and (3) 1.13<NZ<1.50. (In the formulas, Re[450] and Re[550] are values of the in-plane phase difference of the phase difference film measure at 23C by using light with wavelengths of 450 nm and 550 nm respectively; Δn is a value of in-plane birefringence and equals to nx−ny, wherein nx and ny are the refractive indexes of the phase difference film in the slow axis direction and the fast axis direction respectively; and NZ is a ratio of the birefringence in the thickness direction nx−nz to the in-plane birefringence, wherein nz is the refractive index of the phase difference film in the thickness direction.)

A pressure-sensitive adhesive layer for adhesion to other members such as a liquid crystal cell can be provided in the polarizing film described above and an optical film in which at least one of the polarizing films are laminated. The pressure-sensitive adhesive to form the pressure-sensitive adhesive layer is not especially limited. However, an example is a pressure-sensitive adhesive using a polymer such as an acrylic polymer, a silicone-based polymer, polyester, polyurethane, polyamide, polyether, a fluorine-based polymer, and a rubber-based polymer as a base polymer. Especially, an acrylic pressure-sensitive adhesive can be preferably used having excellent optical transparency, an adequate wetting property, adequate pressure-sensitive adhesive characteristics such as a cohesion property and an adhesion property, and excellent weather resistance and heat resistance.

The pressure-sensitive adhesive layer can be provided on one side or both sides of the polarizing film and the optical film as a superimposed layer of layers with different compositions and types. When the pressure-sensitive adhesive layer is provided on the both sides of the films, a layer with different composition, type, or thickness can be provided on each of the front and back sides of the polarizing film or the optical film as a pressure-sensitive adhesive layer. The thickness of the pressure-sensitive layer is appropriately selected depending on the use, the adhering force, etc. In general, the thickness of the pressure-sensitive lay is 1 μm to 500 μm, preferably 1 μm to 200 μm, and especially preferably 1 μm to 100 μm.

In order to prevent contamination, a separator is pre-fixed to cover the exposed surface of the pressure-sensitive adhesive layer until the pressure-sensitive adhesive layer is put in a practical use. Herewith, the pressure-sensitive adhesive layer is prevented from being touched during normal handling. A conventional separator, not considering the thickness limitation, can be used. Examples of the separator include a plastic film, a rubber sheet, paper, cloth, unwoven cloth, a net, a foaming sheet, a metal foil, and a foliate body such as a laminate of these materials coated with an appropriate peeling agent such as a silicone-based agent, a long chain alkyl agent, a fluorine-based agent, and molybdenum sulfide if necessary.

### <Image Display Device>

The polarizing film or the optical film of the present invention can be preferably used to form various types of devices such as a liquid crystal display device. The liquid crystal display device can be formed with the conventional method. In general, a liquid crystal cell and a polarizing film or an optical film and other components such as an illumination system if necessary are appropriately assembled and a driver is incorporated to form a liquid crystal display device. In the present invention, the conventional method is used without limitation. However, the polarizing film or the optical film according to the present invention are used in the method of the present invention. An appropriate type of a liquid crystal cell is used such as a TN type, an STN type, and a n type.

An appropriate liquid crystal display device can be formed such as a liquid crystal display device in which a polarizing film or an optical film is arranged on one side or both sides of the liquid crystal cell and a liquid crystal display device using a backlight or a reflection plate as the illumination system. In this case, the polarizing film or the optical film according to the present invention can be arranged on one side or both sides of the liquid crystal cell. When the polarizing film or the optical film is provided on both sides of the polarizing film or the optical film, each film may be the same or different. One or more layers of appropriate components can be arranged in an appropriate position such as a diffusion plate, an antiglare layer, an antireflection film, a protective plate, a prism array, a lens array sheet, a light diffusion plate, and a backlight.

### EXAMPLES

The examples of the present invention will be described below. However, the embodiment of the preset invention is not limited to these.

### <Production of a Thin Polarizer 1>

A polyvinyl alcohol film having an average degree of polymerization of 2,400, a degree of saponification of 99.9 mol %, and a thickness of 30 μm was soaked in a warm water at 30° C. for 60 seconds and swollen. Then, the swollen polyvinyl alcohol film was soaked in an aqueous solution of iodine/potassium iodide (weight ratio=0.5/8) at a concentration of 0.3% and colored while being stretched to 3.5 times. After that, the film was stretched in a boric ester aqueous solution at 65° C. so that the total elongation became 6 times. After stretching, the film was dried in 40° C. oven for 3 minutes to obtain a PVA-based thin polarizer (thickness 12 μm).

### <Production of a Thin Polarizer 2>

A laminate in which a PVA layer having a thickness of 9 μm was formed on a non-crystalline PET base was auxiliary stretched in the air at a temperature of 130° C. to produce a stretched laminate. Then, the stretched laminate was colored to form a colored laminate. The colored laminate was stretched in boric acid-containing water so that the total elongation became 5.94 times to produce an optical film laminate containing a PVA layer having a thickness of 5 μm which is stretched together with a non-crystalline PET base. The optical film laminate having a thickness of 5 μm configuring a thin polarizer 2 was obtained in which the PVA molecules were oriented high-dimensionally in the PVA layer formed on a non-crystalline PET base by the two-step stretching as described above and iodine atoms absorbed by coloring were oriented high-dimensionally in one direction as an iodine ion complex.

### <Transparent Protective Film>

### Triacetyl Cellulose Film

A triacetyl cellulose film having a thickness of 25 μm (trade name: TJ25UL, manufactured by FUJIFILM Corporation) was used as “TAC1”, a triacetyl cellulose film having a thickness of 40 μm (trade name: TJ40ULF, manufactured by FUJIFILM Corporation) was used as “TAC2”, and a triacetyl cellulose film having a thickness of 60 μm (trade name: TG60ULS, manufactured by FUJIFILM Corporation) was used as “TAC3”.

### Phase Difference Triacetyl Cellulose Film

A phase difference triacetyl cellulose film having a thickness of 41 μm (trade name: WVBZ4E4, manufactured by FUJIFILM Corporation) was used as “TAC4”.

### Acrylic Film

An acrylic film having a thickness of 40 μm (trade name: HX-40UC, manufactured by Toyo Kohan Co., Ltd.) was used as “ACRYL”.

### Cycloolefin Film

A cycloolefin film having a thickness of 13 μm (trade name: ZF14-013, manufactured by ZEON CORPORATION) was used as “COP1”, and a cycloolefin film having a thickness of 25 μm (trade name: ZF14-025, manufactured by ZEON CORPORATION) was used as “COP2”.

### <Active Energy Rays>

As the active energy rays, visible rays (a gallium-sealed metal halide lamp) were used (Irradiation device: Light HAMMER 10 manufactured by Fusion UV systems, Inc., Bulb: V bulb, Peak illumination: 1,600 mW/cm², Integrated irradiation: 1,000/mJ/cm² (wavelength 380 nm to 440 nm)). The illumination of the visible rays was measured by using a Sola-Check system manufactured by Solatell Ltd.

### (Preparation of the Active Energy Ray-Curable Adhesive Composition) Examples 1 to 10, Comparative Examples 1 to 5

According to the recipe described in Table 2, each of the components described below was mixed together and stirred at 50° C. for 1 hour to obtain each of the active energy ray-curable adhesive compositions used in Examples 1 to 10 and Comparative Examples 1 to 5. In the table, the unit of each value is % by weight when the total amount of the composition is 100% by weight.

(1) Active energy ray-curable compound (A) (below, simply referred to “Component A”)

HEAA (hydroxyethyl acrylamide), SP value: 29.5, acrylic equivalent: 115.15, trade name: “HEAA” manufactured by KJ Chemicals Corporation

(2) Active energy ray-curable compound (B) (below, simply referred to “Component B”)

1,9NDA (1,9-nonanediol diacrylate), SP value: 19.2, acrylic equivalent: 134, trade name “LIGHT ACRYLATE 1.9ND-A” manufactured by KYOEISHA CHEMICAL Co., LTD

DCP-A (tricyclodecane dimethanol diacrylate), SP value: 20.3, acrylic equivalent: 152.19, trade name: “LIGHT ACRYLATE DCP-A” manufactured by KYOEISHA CHEMICAL Co., LTD)

HPPA (hydroxypivalic acid neoppentylglycol acrylic acid adduct), SP value: 19.6, acrylic equivalent: 156.18, trade name: “LIGHT ACRYLATE HPP-A” manufactured by KYOEISHA CHEMICAL Co., LTD

P2H-A (phenoxydiethylene glycol acrylate), SP value: 20.4, acrylic equivalent: 236.26, trade name: “LIGHT ACRYLATE P2H-A” manufactured by KYOEISHA CHEMICAL Co., LTD

(3) Active energy ray-curable compound (C) (below, simply referred to “Component C”)

ACMO (acryloylmorphorine), SP value: 22.9, acrylic equivalent: 141.17, trade name: “ACMO” manufactured by KJ Chemicals Corporation

4HBA (4-hydroxybutylacrylate), SP value: 23.8, acrylic equivalent: 144.2, manufactured by OSAKA ORGANIC CHEMICAL INDUSTRY LTD.

M-5700: 2-hydroxy-3-phenoxypropylacrylate, SP value: 24.4, acrylic equivalent: 222.24, trade name: “ARONIX M-5700” manufactured by TOAGOSEI CO., LTD.

(4) Acrylic oligomer (D) formed by polymerizing a (meth)acrylic monomer (below, simply referred to “Component D”)

UP1190, trade name: “ARUFON UP1190” manufactured by TOAGOSEI CO., LTD.

(5) Boric acid group-containing compound (a compound represented by the formula (1))

4-vinylphenylboronic acid, acrylic equivalent: 180.2

(6) Radical polymerization initiator having a hydrogen extraction effect

KAYACURE DETX-S(diethylthioxanthone, a compound represented by the formula (2), trade name: “KAYACURE DETX-S” manufactured by Nippon Kayaku Co., Ltd.

(7) Photopolymerization initiator

IRGACURE 907 (2-methyl-1-(4-methylthiophenyl)-2-morpholinopropane-1 on, a compound represented by the formula(3)), trade name: IRGACURE 907″ manufactured by BASF SE

### (Production of a Polarizing Film)

### Example 1

A wire bar (No. 2, manufactured by Daiichi Rika K.K.) was used to coat the laminating side of the thin polarizer 1 with an easy adhesive composition containing 0.3% by weight of 4-vinylphenylboronic acid in isopropyl alcohol. The easy adhesive composition was dried in a blast of air at 60° C. for one minute to remove the solvent and the thin polarizer 1 having an easy adhesive layer on one side was produced. Then, an MCD coater (manufactured by FUJI CORPORATION) (cell shape: honeycomb, number of gravure roll wires: 1,000 wires/inch, a ratio of the rotational speed to the line speed: 140%) was used to coat the laminating side of the transparent protective film with the active energy ray-curable adhesive composition in which each ingredient was prepared according to the compounding amount described in Table 1 to 0.7 μm thick. Then, the laminating side of the transparent protective film was laminated by using a roller to the side of the thin polarizer 1 where the easy adhesive layer was formed. After that, the laminated transparent protective film was irradiated with the visible rays by using an active energy ray irradiation device to cure the active energy ray-curable adhesive. Then, the laminate was dried in a blast hot air at 70° C. for 3 minutes to obtain a polarizing film having the thin polarizer 1 and the transparent protective film on one side. The line speed of lamination was 25 m/min.

### (Production of a Polarizing Film)

### Examples 2 to 10, Comparative Examples 1 to 5

A wire bar (No. 2, manufactured by Daiichi Rika Co., Ltd.) was used to coat the surface of the thin polarizer 2 of the optical film laminate having the thin polarizer 2 with an easy adhesive composition containing 0.3% by weight of 4-vinylphenylboronic acid in isopropyl alcohol. The easy adhesive composition was dried in a blast of air at 60° C. for one minute to remove the solvent and a polarizer having an easy adhesive layer was produced. Then, an MCD coater (manufactured by FUJI CORPORATION) (cell shape: honeycomb, number of gravure roll wires: 1,000 wires/inch, rotational speed: 140%/line speed) was used to coat the laminating side of the transparent protective film with the active energy ray-curable adhesive composition in which each ingredient was prepared according to the compounding amount described in Table 2 to 0.7 μm thick. Then, the laminating side of the transparent protective film was laminated by using a roller to the side of the thin polarizer with an easy adhesive layer. After that, the laminated transparent protective film was irradiated with the visible rays by using an active energy ray irradiation device to cure the active energy ray-curable adhesive. Then, the laminate was dried in a blast hot air at 70° C. for 3 minutes. After that, the non-crystalline PET base was peeled to obtain a polarizing film having a thin polarizing film. The line speed of lamination was 25 m/min.

### <Measurement of a Thickness of the Compatible Layer>

In order to observe the cross-section of the film, a test piece produced with a super thin cutting method was observed by using a transmission electron microscope (TEM) (trade name: “H-7650” manufactured by Hitachi, Ltd. with an acceleration speed of 100 kV. A TEM picture of the test piece was taken to confirm the compatible layer and measure a thickness of the compatible layer.

### <Crack Evaluation: A Heat Shock Test>

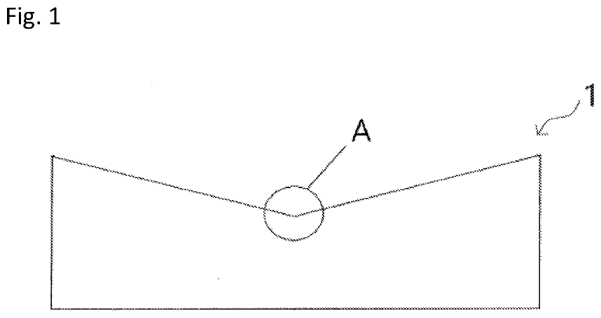

A pressure-sensitive layer was provided on the transparent protective film side of the polarizing film obtained in each of the examples and the comparative examples to prepare a polarizing film with a pressure-sensitive adhesive layer. The polarizing film with a pressure-sensitive adhesive layer was cut into pieces in which each has a shape shown in FIG. 1 (a rectangle of 50 mm×150 mm and one adjacent pair of the angles between the long side and the short side is 14° (a direction of the absorption axis is 50 mm)) by using a CO₂ laser (trade name: Laser Pro-SPIRIT manufactured by COMNET Inc. The polarizing film with a pressure-sensitive adhesive layer 1 having the prescribed shape was laminated to a non-alkaline glass having a thickness of 0.5 mm to produce a sample. The sample was placed in an environment in which a heat shock changing the temperature from −40° C. to 85° C. each lasting for 30 minutes was repeated 200 times. Then the generation of the through cracks was confirmed in the portion A of the polarizing film with a pressure-sensitive adhesive layer 1 shown in FIG. 1 (V-shaped part on one long side of the polarizing film with a pressure-sensitive adhesive layer). This test was repeated 10 times, and the case when the crack was generated was marked “X”, and the case when the crack was not generated was marked “0”. The irradiation conditions of the CO₂ laser were as follows.

### (Irradiation Conditions)

Wavelength: 10.6 μm

Laser output: 30 W

Oscillation mode: pulsed oscillation

Diameter of the laser beam: 70 μm

Direction of irradiation: toward the protective film

### <Optical Durability of the Polarizing Film>

The transmittance and the degree of the polarizing film were measured by using a spectral transmittance measuring device with an integrating sphere (“Dot-3c” manufactured by MURAKAMI COLOR RESEARCH LABORATORY CO., LTD.)

The degree of polarization P can be obtained by the following formula:

P(%)={(Tp−Tc)/(Tp+Tc)}^{1/2}×100,

wherein the transmittance (parallel transmittance: Tp) was obtained when two of the same polarizing films were laminated together so that the axes of transmission were parallel to each other and the transmittance (orthogonal transmittance: Tc) was obtained when two of the same polarizing films were laminated together so that the axes of transmission were orthogonal to each other.

Each transmittance was obtained as a Y value calculated by visibly correcting the transmitted light by a 2-degree field of vision (a C light source) described in JIS 28701 with a reference to the completely polarized light obtained through a Glan-Taylor prism polarizer as being 100%.

A corona treatment was performed on the polarizing film side of this polarizing film. Then, an acrylic pressure-sensitive adhesive having a thickness of 20 μm was laminated to the polarizing film side, and a non-alkaline glass was laminated on another side of the acrylic pressure-sensitive adhesive to measure the initial values the degree of polarization P and the transmittance based on the definition described above. Then, this polarizing film with a glass was placed in an environment of 65° C. and 90% RH for 250 hours, and the degree of polarization P and the transmittance were measured after the exposure to the environment. A change of the degree of polarization (Δ_{(Degree of Polarization P)}) was calculated by subtracting the initial degree of polarization P from the degree of polarization P after the exposure to the environment, and a change of the transmittance (Δ_{(Transmittance)}) was calculated by 01subtracting the initial transmittance from the transmittance after the exposure to the environment. The Δ_{(Transmittance)} of 1.3 or less means that the optical durability was good, and the Δ_{(Transmittance)} exceeding 1.3 means that the optical durability was deteriorated. The Δ_{(Degree of Polarization P)} of more than −0.1 means that the optical durability was good, and the Δ_{(Degree of Polarization P)} of −0.1 or less means that the optical durability was deteriorated.

### <Adhering Force>

The polarizing film was cut into pieces, each piece having a size of 200 mm in parallel to the stretching direction of the polarizer and 15 mm in orthogonal to the stretching direction of the polarizer. The polarizing film was laminated onto a glass plate. A slit cut was made between the protective film and the polarizer by using a utility knife and the protective film and the polarizer were peeled in the 90° direction at a peeling speed of 1,000 mm/min to measure the peeling strength (N/15 mm). When the peeling strength exceed 1.3 (N/15 mm), the adhering force is excellent; when the peeling strength is 1.0 N/mm to 1.3 N/mm, the adhering force is in a practical level; and when the adhesion force is less than 1.0 (N/mm), the adhering force is poor.

TABLE 2

| | | SP | Equiv- | Exam- | Exam- | Exam- | Exam- | Exam- | Exam- | Exam- | Exam- | Exam- |
|---|---|---|---|---|---|---|---|---|---|---|---|---|
| | | Value | alent | ple 1 | ple 2 | ple 3 | ple 4 | ple 5 | ple 6 | ple 7 | ple 8 | ple 9 |
| Component C | ACMO | 22.9 | 141.17 | 45 | 45 | 45 | 45 | 10 | 40 | 44 | 50 | 45 |
| | 4HBA | 23.8 | 144.2 | | | | | 15 | 20 | | | |
| | M-5700 | 24.4 | 222.24 | | | | | | | | | |
| Component B | 1,9NDA | 19.2 | 134 | | | | | 20 | 30 | | 50 | |
| | DCP-A | 20.3 | 152.19 | 45 | 45 | 45 | 45 | 20 | | 45 | | 45 |
| | HPPA | 19.6 | 156.18 | | | | | 10 | | | | |
| | P2H-A | 20.4 | 236.26 | | | | | 15 | | | | |
| Component A | HEAA | 29.5 | 115.15 | | | | | | | 1 | | |

| Component D | UP1190 | | 10 | 10 | 10 | 10 | 10 | 10 | 10 | | 10 |
|---|---|---|---|---|---|---|---|---|---|---|---|
| 4-Vinylphenylboric Acid | | 180.2 | | | | | | | | | |
| Photopolymer- | IRGACURE907 | | 3 | 3 | 3 | 3 | 3 | 3 | 3 | 3 | 3 |
| ization | KAYACURE-DETXS | | 1.5 | 1.5 | 1.5 | 1.5 | 1.5 | 1.5 | 1.5 | 1.5 | 1.5 |
| Initiator | | | | | | | | | | | |
| Type of Polarizer | | | Thin | Thin | Thin | Thin | Thin | Thin | Thin | Thin | TThin |
| | | | Polar- | Polar- | Polar- | Polar- | Polar- | Polar- | Polar- | Polar- | Polar- |
| | | | izer 1 | izer 2 | izer 2 | izer 2 | izer 2 | izer 2 | izer 2 | izer 2 | izer 2 |
| Thickness of Polarizer | | | 12 | 5 | 5 | 5 | 5 | 5 | 5 | 5 | 5 |
| Acrylic Equivalent of Composition | | | 170 | 170 | 170 | 170 | 179 | 162 | 170 | 144 | 170 |
| Type of Transparent Protective Film | | | TAC1 | TAC1 | TAC2 | TAC3 | TAC3 | TAC3 | TAC3 | TAC1 | TAC4 |
| Thickness of Transparent Protective Film (μm) | | | 25 | 25 | 40 | 60 | 60 | 60 | 60 | 25 | 41 |
| Thickness of Compatible Layer (μm) | | | 0.5 | 0.5 | 0.5 | 0.5 | 0.2 | 0.3 | 0.5 | 0.4 | 0.5 |
| Parameter (P × Q) | | | 5 | 5 | 5 | 5 | 2 | 3 | 5 | — | 5 |
| Evaluation of Crack | | | ∘ | ∘ | ∘ | ∘ | ∘ | ∘ | ∘ | ∘ | ∘ |
| Optical | Δ_{(Transmittance)} | | 1.2 | 1.1 | 1.1 | 1 | 1 | 1.3 | 1.2 | 1.2 | 0.9 |
| Durability | Δ_{(Degree of Polarization P)} | | −0.04 | −0.05 | −0.05 | −0.05 | −0.03 | −0.07 | −0.05 | −0.04 | −0.04 |

| | | | | | | | | | |
|---|---|---|---|---|---|---|---|---|---|
| Adhering Froce [N/15 mm] | 1.8 | 2.0 | 1.9 | 1.9 | 1.3 | 2.0 | 2.0 | 1.2 | 1.4 |

| | | | | Comparative | Comparative | Comparative | Comparative | Comparative |
|---|---|---|---|---|---|---|---|---|
| | | SP | Exam- | Exam- | Exam- | Exam- | Exam- | Exam- |
| | | Value | ple 10 | ple 1 | ple 2 | ple 3 | ple 4 | ple 5 |
| Component C | ACMO | 22.9 | 45 | 35 | 5 | 55 | 43 | 45 |
| | 4HBA | 23.8 | | | 20 | | | |
| | M-5700 | 24.4 | | | | | | |
| Component B | 1,9NDA | 19.2 | | | 54 | | | |
| | DCP-A | 20.3 | 50 | | | 45 | 45 | 35 |
| | HPPA | 19.6 | | 34 | | | | |
| | P2H-A | 20.4 | | | | | | |
| Component A | HEAA | 29.5 | | 30 | 14 | | | 10 |

| Component D | UP1190 | 5 | | 10 | 10 | 10 | 10 |
|---|---|---|---|---|---|---|---|
| 4-Vinylphenylboric Acid | | | | 2 | | | |
| Photopolymer- | IRGACURE907 | 3 | 3 | 3 | 3 | 3 | 3 |
| ization | KAYACURE-DETXS | 1.5 | 1.5 | 1.5 | 1.5 | 1.5 | 1.5 |
| Initiator | | | | | | | |
| Type of Polarizer | | Thin | Thin | Thin | Thin | Thin | Thin |
| | | Polar- | Polar- | Polar- | Polar- | Polar- | Polar- |
| | | izer 2 | izer 2 | izer 2 | izer 2 | izer 2 | izer 2 |
| Thickness of Polarizer | | 5 | 5 | 5 | 5 | 5 | 5 |
| Acrylic Equivalent of Composition | | 161 | 143 | 154 | 167 | 171 | 164 |
| Type of Transparent Protective Film | | TAC4 | TAC3 | TAC3 | ACRYL | COP1 | COP2 |
| Thickness of Transparent Protective Film (μm) | | 41 | 60 | 60 | 40 | 13 | 25 |
| Thickness of Compatible Layer (μm) | | 0.5 | 0.1 | 0.2 | 0.1 | 0 | 0 |
| Parameter (P × Q) | | 2.5 | — | 2 | 1 | — | — |
| Evaluation of Crack | | ∘ | ∘ | ∘ | x | x | x |
| Optical | Δ_{(Transmittance)} | 1 | 3.8 | 2.3 | 1.2 | 1.1 | 1 |
| Durability | Δ_{(Degree of Polarization P)} | −0.04 | −6.3 | −1.45 | −0.05 | −0.06 | −0.05 |

| | | | | | | |
|---|---|---|---|---|---|---|
| Adhering Froce [N/15 mm] | 1.3 | 1.5 | 1.6 | 2.5 | 0.2 | 1.2 |

1. A polarizing film, wherein
a transparent protective film is provided on at least one side of a polarizer through an adhesive layer,
the transparent protective film is a cellulose-based resin film,
the adhesive layer is formed by a cured layer obtained by irradiating an active energy ray-curable adhesive composition with active energy rays, and
the active energy ray-curable adhesive composition contains 0.0% by weight to 4.0% by weight of an active energy ray-curable compound (A) having an SP value of 29.0 (MJ/m³)^{1/2} to 32.0 (MJ/m³)^{1/2}, 5.0% by weight to 98.0% by weight of an active energy ray-curable compound (B) having the SP value of 18.0 (MJ/m³)^{1/2} to 21.0 (MJ/m³)^{1/2} (exclusive of 21.0 (MJ/m³)^{1/2}), and 5.0% by weight to 98.0% by weight of an active energy ray-curable compound (C) having the SP value of 21.0 (MJ/m³)^{1/2} to 26.0 (MJ/m³)^{1/2} on a basis of 100% by weight of a total amount of the composition.

2. The polarizing film according to claim 1, wherein a thickness of the polarizer is 3 μm to 15 μm.

3. The polarizing film according to claim 1, wherein the active energy ray-curable adhesive composition contains 20% by weight to 80% by weight of the active energy ray-curable compound (B) on the basis of 100% by weight of the total amount of the composition.

4. The polarizing film according to claim 1,
wherein the active energy ray-curable adhesive composition contains an acrylic oligomer (D) obtained by polymerizing a (meth)acrylic monomer.

5. The polarizing film according to claim 1, wherein an acrylic equivalent Cₐₑ of the active energy ray-curable adhesive composition represented by a following equation (1) is 140 or more,
Cₐₑ=1/Σ(W_{N}/Nₐₑ) (1)
where W_{N} represents a mass fraction of an active energy ray-curable compound N in the composition, and Nₐₑ represents an acrylic equivalent of the active energy ray-curable compound N.

6. The polarizing film according to claim 1, wherein the active energy ray-curable adhesive composition contains a radical polymerization initiator having a hydrogen extraction effect.

7. The polarizing film according to claim 6, wherein the radical polymerization initiator is a thioxanthone-based radical polymerization initiator.

8. The polarizing film according to claim 1, wherein
the active energy ray-curable adhesive composition contains the acrylic oligomer (D),
a compatible layer is formed between the transparent protective film and the adhesive layer, where a composition thereof changes continuously, and
a value of P×Q is less than 10, where P (μm) represents a thickness of the compatible layer and Q (% by weight) represents a content of the acrylic oligomer (D) on the basis of 100% by weight of the total amount of the composition.

9. The polarizing film according to claim 1 having a compound represented by a following formula (1): 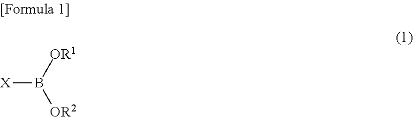
(wherein, X represents a functional group including a reactive group and R¹ and R² represent each independently a hydrogen atom, an aliphatic hydrocarbon group which may have a substituent, an aryl group which may have a substituent, or a heterocyclic group which may have a substituent) provided on at least one of the laminating sides of the polarizer and the transparent protective film, wherein
the compound represented by the formula (1) lies between the polarizer and the adhesive layer and/or between the transparent protective film and the adhesive layer.

10. The polarizing film according to claim 9, wherein the compound represented by the formula (1) is a compound represented by a following formula (1′) 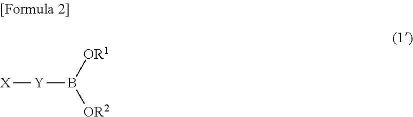
(wherein, Y represents an organic group; and X, R¹, and R² are the same as described above).

11. The polarizing film according to claim 9 having the compound represented by the formula (1) on the laminating side of the polarizer.

12. The polarizing film according to claim 9, wherein the reactive group in the compound represented by the formula (1) is at least one type of the reactive groups selected from a group consisting of α,β-unsaturated carbonyl group, a vinyl group, a vinylether group, an epoxy group, an oxetane group, an amino group, an aldehyde group, a mercapto group, and a halogen group.

13. A method for manufacturing a polarizing film comprising:
a coating step of coating an active energy ray-curable adhesive composition on at least one of sides of a polarizer and a transparent protective film;
a laminating step of laminating the polarizer and the transparent protective film; and
an adhering step of adhering the transparent protective film to the polarizer through an adhesive layer obtained by irradiating from the polarizer side or the transparent protective film side with active energy rays to cure the active energy ray-curable adhesive composition, wherein
the transparent protective film is a cellulose-based resin film, and
the active energy ray-curable adhesive composition contains 0.0% by weight to 4.0% by weight of an active energy ray-curable compound (A) having the SP value of 29.0(MJ/m³)^{1/2} to 32.0 (MJ/m³)^{1/2}, 5.0% by weight to 98.0% by weight of an active energy ray-curable compound (B) having the SP value of 18.0 (MJ/m³)^{1/2} to 21.0 (MJ/m³)^{1/2} (exclusive of 21.0 (MJ/m³)^{1/2}), and 5.0% by weight to 98.0% by weight of an active energy ray-curable compound (C) having the SP value of 21.0 (MJ/m³)^{1/2} to 26.0 (MJ/m³)^{1/2} on the basis of 100% by weight of the total amount of the composition.

14. The method for manufacturing a polarizing film according to claim 13, wherein a thickness of the polarizer is 3 μm to 15 μm.

15. The method for manufacturing a polarizing film according to claim 13 containing an adhesion facilitating treatment step of attaching the compound represented by the following formula (1): 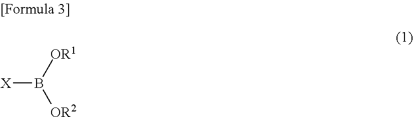
(wherein, X represents a functional group including a reactive group and R¹ and R² represent each independently a hydrogen atom, an aliphatic hydrocarbon group which may have a substituent, an aryl group which may have a substituent, or a heterocyclic group which may have a substituent) onto at least one of the laminating sides of the polarizer and the transparent protective film.

16. The method for manufacturing a polarizing film according to claim 13, wherein the compound represented by the Formula (1) is a compound represented by the following formula (1′) 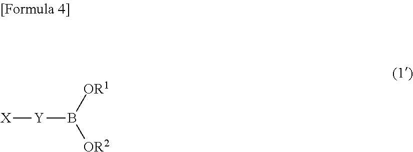
(wherein, Y represents an organic group; and X, R¹, and R² are the same as described above).

17. The method for manufacturing a polarizing film according to claim 13, wherein a corona treatment, a plasma treatment, an excimer treatment, or a frame treatment is performed on the laminating side which is at least one of the sides of the polarizer and the transparent protective film before the coating step.

18. The method for manufacturing a polarizing film according to claim 13, wherein the active energy rays contain visible rays having a wavelength region of 380 nm to 450 nm.

19. The method for manufacturing a polarizing film according to claim 13, wherein a ratio of an integral illuminance of a wavelength region of 380 nm to 440 nm of the active energy rays to an integral illuminance of a wavelength region of 250 nm to 370 nm of the active energy rays is 100:0 to 100:50.

20. An optical film, wherein at least one of the polarizing films according to claim 1 is laminated.

21. An image display device, wherein the polarizing film according to claim 1 is used.
